(19) United States
(12) Patent Application Publication
(10) Pub. No.: US 2012/0153970 A1
(43) Pub. Date: Jun. 21, 2012

(54) CAPACITIVE TOUCH SENSING DEVICES AND METHODS OF MANUFACTURING THEREOF

(75) Inventors: Marc Maurice Mignard, San Jose, CA (US); Donald J. Elloway, Campbell, CA (US); Russel A. Martin, Menlo Park, CA (US); Alok Govil, Santa Clara, CA (US)

(73) Assignee: QUALCOMM MEMS Technologies, Inc., San Diego, CA (US)

(21) Appl. No.: 12/975,025

(22) Filed: Dec. 21, 2010

(51) Int. Cl. G01R 27/26; H01R 43/00

(52) U.S. Cl. 324/658; 29/825

(57) ABSTRACT

The present disclosure provides systems, methods, and apparatus for sensing the location(s) of conductive objects disposed near a sensor array. In one aspect, a sensor array includes a conductive row and a conductive column formed of non-transparent material(s). At least a portion of the conductive row overlaps at least a portion of the conductive column and each of the conductive rows and columns include sensing elements. The sensing elements at least partially define volumes including non-conductive and optically transparent material(s) to limit the loss of light that passes therethrough.

### TECHNICAL FIELD

This disclosure relates to sensing devices, and more specifically to capacitive touch sensors.

### DESCRIPTION OF THE RELATED TECHNOLOGY

Electromechanical systems include devices having electrical and mechanical elements, actuators, transducers, sensors, optical components (e.g., mirrors) and electronics. Electromechanical systems can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

One type of electromechanical systems device is called an interferometric modulator (IMOD). As used herein, the term interferometric modulator or interferometric light modulator refers to a device that selectively absorbs and/or reflects light using the principles of optical interference. In some implementations, an interferometric modulator may include a pair of conductive plates, one or both of which may be transparent and/or reflective, wholly or in part, and capable of relative motion upon application of an appropriate electrical signal. In an implementation, one plate may include a stationary layer deposited on a substrate and the other plate may include a reflective membrane separated from the stationary layer by an air gap. The position of one plate in relation to another can change the optical interference of light incident on the interferometric modulator. Interferometric modulator devices have a wide range of applications, and are anticipated to be used in improving existing products and creating new products, especially those with display capabilities.

Many existing capacitive touch sensing devices for touch screens include electrically isolated conductive rows and columns formed from conductive materials, for example, indium tin oxide (ITO) that are used to detect the location of a conductive object, e.g., a finger, over the sensing device. These sensing devices can be disposed over displays such that the underlying displays are visible through the sensing devices. However, transparent conductors can absorb and reflect incident light, which can decrease the brightness of an underlying reflective display to undesirable levels.

### SUMMARY

The systems, methods, and devices of the present disclosure each have several innovative aspects, no single one of which is solely responsible for the desirable attributes disclosed herein.

One innovative aspect of the subject matter described in this disclosure can be implemented in a sensor array. The sensor array can include a conductive row including a non-transparent material and the conductive row can form a first sensing element that at least partially defines a first volume. The first volume can include a non-conductive and optically transparent material. The sensor array also can include a conductive column including a non-transparent material and the conductive column can form a second sensing element that at least partially defines a second volume. The second volume can include a non-conductive and optically transparent material. In one aspect, at least a portion of the conductive row can overlap at least a portion of the conductive column. In one aspect, the sensor array can also include a reflectivity control layer disposed over at least a portion of the conductive row and/or the conductive column. The reflectivity control layer can include black chrome, a polymer, and/or an interferometric stack.

One innovative aspect described in this disclosure can be implemented in a sensor array. The sensor array can include first means for conducting electric current which can include a non-transparent material and the first conductive means can form a first sensing means that at least partially defines a volume that includes a non-conductive and optically transparent material. The sensor array can also include second means for conducting electric current which can include a non-transparent material and the second conductive means can form a second sensing means that at least partially defines a volume that includes a non-conductive and optically transparent material. In one aspect, at least a portion of the first conductive means can overlap at least a portion of the second conductive means. The sensor array can also include a reflectivity control means disposed over at least a portion of the first conductive means and/or the second conductive means.

One innovative aspect of the subject matter described in this disclosure can be implemented in a method of manufacturing a sensor array including forming a conductive row including a non-transparent material. The conductive row can include a first sensing element that at least partially defines a first volume that includes a non-conductive and optically transparent material. The method can also include forming a conductive column including a non-transparent material. The conductive column can include a second sensing element that at least partially defines a second volume that includes a non-conductive and optically transparent material. In one aspect, at least a portion of the conductive row can overlap at least a portion of the conductive column. In one aspect, the method can include disposing the conductive row and the conductive column over a reflective display. In aspect, the method can include disposing a reflectivity control layer over at least a portion of the conductive row or conductive column.

Another innovative aspect described in this disclosure can be implemented in a sensor array including a conductive row including a non-transparent material and a first segment. The sensor array can also include a conductive column including a non-transparent material and a second segment. The first segment can extend substantially parallel to the second segment and the first and second segments can at least partially define a volume therebetween that includes a non-conductive and optically transparent material. In one aspect, the sensor array can also include a first reflectivity control layer disposed over at least a portion of the conductive row and/or can also include a second reflectivity control layer disposed over at least a portion of the conductive column.

Another innovative aspect described in this disclosure can be implemented in a sensor array. The sensor array can include can include first means for conducting electric current. The first conductive means can include a non-transparent material including a first segment. The sensor array can also include second means for conducting electric current. The second conductive means can include a non-transparent material including a second segment. The first segment can be substantially parallel to the second segment and the first and second segments can at least partially define a volume therebetween that includes a non-conductive and optically transparent material. In one aspect, the sensor array can also include a first reflectivity control means disposed over at least a portion of the first conductive means and/or can include a second reflectivity control means disposed over at least a portion of the second conductive means.

One innovative aspect of the subject matter described in this disclosure can be implemented in a method of manufacturing a sensor array. The method can include forming a conductive row including a non-transparent material. The conductive row can include a first segment. The method can also include forming a conductive column including a non-transparent material. The conductive column can include a second segment that extends generally parallel to the first segment such that the first and second segments at least partially defines a volume therebetween that includes a non-conductive and optically transparent material. In one aspect, the method can include disposing the conductive row and the conductive column over a reflective display.

Another innovative aspect of the subject matter described in this disclosure can be implemented in a sensor array. The sensor array can include a conductive row including a first sensing element that at least partially defines a first volume. The first volume can include a non-conductive and optically transparent material. The sensor array also can include a conductive column including a second sensing element that at least partially defines a second volume. The second volume can include a non-conductive and optically transparent material. In one aspect, at least a portion of the conductive row can overlap at least a portion of the conductive column. In one aspect, the sensor array can also include a reflectivity control layer disposed over at least a portion of the conductive row and/or the conductive column. The reflectivity control layer can include black chrome, a polymer, and/or an interferometric stack.

One innovative aspect described in this disclosure can be implemented in a sensor array. The sensor array can include first means for conducting electric current which can include a first sensing means that at least partially defines a volume that includes a non-conductive and optically transparent material. The sensor array can also include second means for conducting electric current which can include a second sensing means that at least partially defines a volume that includes a non-conductive and optically transparent material. In one aspect, at least a portion of the first conductive means can overlap at least a portion of the second conductive means. The sensor array can also include a reflectivity control means disposed over at least a portion of the first conductive means and/or the second conductive means.

One innovative aspect of the subject matter described in this disclosure can be implemented in a method of manufacturing a sensor array including forming a conductive row including a first sensing element that at least partially defines a first volume that includes a non-conductive and optically transparent material. The method can also include forming a conductive column including a second sensing element that at least partially defines a second volume that includes a non-conductive and optically transparent material. In one aspect, at least a portion of the conductive row can overlap at least a portion of the conductive column. In one aspect, the method can include disposing the conductive row and the conductive column over a reflective display. In aspect, the method can include disposing a reflectivity control layer over at least a portion of the conductive row or conductive column.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 shows an example of an isometric view depicting two adjacent pixels in a series of pixels of an interferometric modulator (IMOD) display device.

FIG. 2 shows an example of a system block diagram illustrating an electronic device incorporating a 3×3 interferometric modulator display.

FIG. 3 shows an example of a diagram illustrating movable reflective layer position versus applied voltage for the interferometric modulator of FIG. 1.

FIG. 4 shows an example of a table illustrating various states of an interferometric modulator when various common and segment voltages are applied.

FIG. 5A shows an example of a diagram illustrating a frame of display data in the 3×3 interferometric modulator display of FIG. 2.

FIG. 5B shows an example of a timing diagram for common and segment signals that may be used to write the frame of display data illustrated in FIG. 5A.

FIG. 6A shows an example of a partial cross-section of the interferometric modulator display of FIG. 1.

FIGS. 6B-6E show examples of cross-sections of varying implementations of interferometric modulators.

FIG. 7 shows an example of a flow diagram illustrating a manufacturing process for an interferometric modulator.

FIGS. 8A-8E show examples of cross-sectional schematic illustrations of various stages in a method of making an interferometric modulator.

FIG. 9A shows a top-side view of an example sensing device having a plurality of conductive rows and columns for detecting a presence of a conductive object over the sensor array.

FIG. 9B shows a flow diagram illustrating an example method of operating a sensing device.

FIGS. 10A and 10B show cross-sections of two example implementations of sensing devices.

FIGS. 11A-11I show top-side views of different implementations of example sensing arrays for use in sensing devices.

FIG. 11J shows a close up view of a portion of the example sensing array of FIG. 11I.

FIG. 12 shows a cross-section of an example implementation of a conductive structure with a reflectivity control layer disposed over the conductive structure.

FIGS. 13A-13C show examples of processes for manufacturing a sensor array.

FIGS. 14A and 14B show examples of system block diagrams illustrating a display device that includes a plurality of interferometric modulators.

Like reference numbers and designations in the various drawings indicate like elements.

### DETAILED DESCRIPTION

The following detailed description is directed to certain implementations for the purposes of describing the innovative aspects. However, the teachings herein can be applied in a multitude of different ways. The described implementations may be implemented in any device that is configured to display an image, whether in motion (e.g., video) or stationary (e.g., still image), and whether textual, graphical or pictorial. More particularly, it is contemplated that the implementations may be implemented in or associated with a variety of electronic devices such as, but not limited to, mobile telephones, multimedia Internet enabled cellular telephones, mobile television receivers, wireless devices, smartphones, bluetooth devices, personal data assistants (PDAs), wireless electronic mail receivers, hand-held or portable computers, netbooks, notebooks, smartbooks, printers, copiers, scanners, facsimile devices, GPS receivers/navigators, cameras, MP3 players, camcorders, game consoles, wrist watches, clocks, calculators, television monitors, flat panel displays, electronic reading devices (e.g., e-readers), computer monitors, auto displays (e.g., odometer display, etc.), cockpit controls and/or displays, camera view displays (e.g., display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, packaging (e.g., MEMS and non-MEMS), aesthetic structures (e.g., display of images on a piece of jewelry) and a variety of electromechanical systems devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes, electronic test equipment. Thus, the teachings are not intended to be limited to the implementations depicted solely in the Figures, but instead have wide applicability as will be readily apparent to one having ordinary skill in the art.

In some implementations, an interferometric display can include one or more sensing devices disposed over at least a portion of the display. These sensing devices can be configured to detect the touch or proximal positioning of a conductive object, for example, a human finger or a stylus. The sensing devices can further be configured to detect the location of the touch or proximal positioning of the conductive object relative to the sensing device and this detected location can be provided to an external circuit, for example, to a computer that controls the underlying display. In such implementations, ambient light incident on the reflective interferometric display first passes through the sensing device toward the interferometric device and then reflects from the display back through the sensing device. Thus, ambient light that is reflected from an interferometric display toward, e.g., a viewer can pass through the sensing device at least two times.

Many existing capacitive touch sensing devices include electrically isolated conductive rows and columns formed of transparent conductors, for example, indium tin oxide (ITO) elements, that are used to detect the location of a conductive object over the sensing device. As the rows and columns of these devices are optically transparent, these sensing devices can be disposed over displays such that the underlying displays are visible through the sensing devices. However, transparent conductors can absorb between about 4% and about 20% of light that passes therethrough. Moreover, transparent conductors can reflect between about 2% and about 8% of light that is incident thereon. Additionally, the total amount of light absorbed and/or reflected by a given transparent conductor increases with the number of times light must pass through the transparent conductor. When transparent conductors are disposed over a reflective display, for example, an interferometric display, the absorption and/or reflection of light by the transparent conductors can be considered “lost light” because it is not reflected by the display and subsequently not observed by a viewer. Lost light can decrease the brightness of a reflective display and require the implementation of supplemental lighting, for example, front lighting.

Various implementations disclosed herein include sensing devices that incorporate sensor arrays for use in capacitive touch sensors. The sensor arrays can be formed by a conductive rows and columns. Each conductive row or column can be formed from a transparent material, semi-transparent material, for example, ITO, or non-transparent material, for example, aluminum or molybdenum. As used herein, “semi-transparent” refers to a material that allows greater than 80% of visible light that is incident thereon to pass therethrough and can include, for example, various transparent conductive oxides. In some implementations, each conductive row and column includes a sensing element that at least partially defines a volume including an optically transparent and non-conductive material. In some other implementations, conductive rows and columns define at least one volume between one another including an optically transparent and non-conductive material. In this way, the conductive rows and columns can be used to sense the location of a proximally located conductive object while allowing light to pass through the optically transparent and non-conductive volumes.

Particular implementations of the subject matter described in this disclosure can be implemented to realize one or more of the following potential advantages. For example, sensor arrays disclosed herein may reduce the amount of incident light that is absorbed and/or reflected by the sensor array as compared to existing sensor arrays. Reducing the amount of light lost through the sensor array can negate supplemental lighting requirements which increase power consumption for a reflective display and result in increased manufacturing costs. Also, the dimensions of the conductive rows and columns can be selected to limit the visibility of the conductive rows and columns over the display. Reflection from the conductive rows and columns can be reduced further by including various reflectivity control layers on the viewer side of the conductive rows and columns.

One example of a suitable MEMS device, to which the described implementations may apply, is a reflective display device. Reflective display devices can incorporate interferometric modulators (IMODs) to selectively absorb and/or reflect light incident thereon using principles of optical interference. IMODs can include an absorber, a reflector that is movable with respect to the absorber, and an optical resonant cavity defined between the absorber and the reflector. The reflector can be moved to two or more different positions, which can change the size of the optical resonant cavity and thereby affect the reflectance of the interferometric modulator. The reflectance spectrums of IMODs can create fairly broad spectral bands which can be shifted across the visible wavelengths to generate different colors. The position of the spectral band can be adjusted by changing the thickness of the optical resonant cavity, i.e., by changing the position of the reflector.

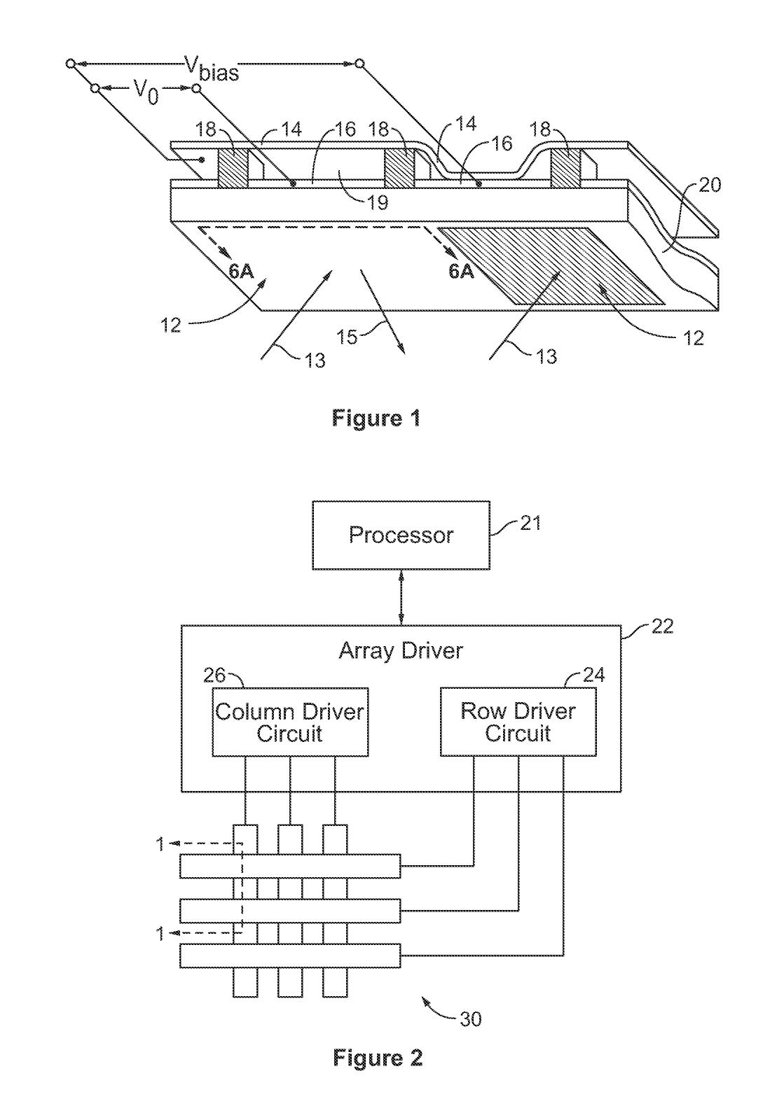

FIG. 1 shows an example of an isometric view depicting two adjacent pixels in a series of pixels of an interferometric modulator (IMOD) display device. The IMOD display device includes one or more interferometric MEMS display elements. In these devices, the pixels of the MEMS display elements can be in either a bright or dark state. In the bright (“relaxed,” “open” or “on”) state, the display element reflects a large portion of incident visible light, e.g., to a user. Conversely, in the dark (“actuated,” “closed” or “off”) state, the display element reflects little incident visible light. In some implementations, the light reflectance properties of the on and off states may be reversed. MEMS pixels can be configured to reflect predominantly at particular wavelengths allowing for a color display in addition to black and white.

The IMOD display device can include a row/column array of IMODs. Each IMOD can include a pair of reflective layers, i.e., a movable reflective layer and a fixed partially reflective layer, positioned at a variable and controllable distance from each other to form an air gap (also referred to as an optical gap or cavity). The movable reflective layer may be moved between at least two positions. In a first position, i.e., a relaxed position, the movable reflective layer can be positioned at a relatively large distance from the fixed partially reflective layer. In a second position, i.e., an actuated position, the movable reflective layer can be positioned more closely to the partially reflective layer. Incident light that reflects from the two layers can interfere constructively or destructively depending on the position of the movable reflective layer, producing either an overall reflective or non-reflective state for each pixel. In some implementations, the IMOD may be in a reflective state when unactuated, reflecting light within the visible spectrum, and may be in a dark state when unactuated, reflecting light outside of the visible range (e.g., infrared light). In some other implementations, however, an IMOD may be in a dark state when unactuated, and in a reflective state when actuated. In some implementations, the introduction of an applied voltage can drive the pixels to change states. In some other implementations, an applied charge can drive the pixels to change states.

The depicted portion of the pixel array in FIG. 1 includes two adjacent interferometric modulators 12. In the IMOD 12 on the left (as illustrated), a movable reflective layer 14 is illustrated in a relaxed position at a predetermined distance from an optical stack 16, which includes a partially reflective layer. The voltage V₀ applied across the IMOD 12 on the left is insufficient to cause actuation of the movable reflective layer 14. In the IMOD 12 on the right, the movable reflective layer 14 is illustrated in an actuated position near or adjacent the optical stack 16. The voltage V_{bias} applied across the IMOD 12 on the right is sufficient to maintain the movable reflective layer 14 in the actuated position.

In FIG. 1, the reflective properties of pixels 12 are generally illustrated with arrows 13 indicating light incident upon the pixels 12, and light 15 reflecting from the pixel 12 on the left. Although not illustrated in detail, it will be understood by one having ordinary skill in the art that most of the light 13 incident upon the pixels 12 will be transmitted through the transparent substrate 20, toward the optical stack 16. A portion of the light incident upon the optical stack 16 will be transmitted through the partially reflective layer of the optical stack 16, and a portion will be reflected back through the transparent substrate 20. The portion of light 13 that is transmitted through the optical stack 16 will be reflected at the movable reflective layer 14, back toward (and through) the transparent substrate 20. Interference (constructive or destructive) between the light reflected from the partially reflective layer of the optical stack 16 and the light reflected from the movable reflective layer 14 will determine the wavelength(s) of light 15 reflected from the pixel 12.

The optical stack 16 can include a single layer or several layers. The layer(s) can include one or more of an electrode layer, a partially reflective and partially transmissive layer and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals, e.g., chromium (Cr), semiconductors, and dielectrics. The partially reflective layer can be formed of one or more layers of materials, and each of the layers can be formed of a single material or a combination of materials. In some implementations, the optical stack 16 can include a single semi-transparent thickness of metal or semiconductor which serves as both an optical absorber and conductor, while different, more conductive layers or portions (e.g., of the optical stack 16 or of other structures of the IMOD) can serve to bus signals between IMOD pixels. The optical stack 16 also can include one or more insulating or dielectric layers covering one or more conductive layers or a conductive/absorptive layer.

In some implementations, the layer(s) of the optical stack 16 can be patterned into parallel strips, and may form row electrodes in a display device as described further below. As will be understood by one having skill in the art, the term “patterned” is used herein to refer to masking as well as etching processes. In some implementations, a highly conductive and reflective material, such as aluminum (Al), may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of posts 18 and an intervening sacrificial material deposited between the posts 18. When the sacrificial material is etched away, a defined gap 19, or optical cavity, can be formed between the movable reflective layer 14 and the optical stack 16. In some implementations, the spacing between posts 18 may be on the order of 1-1000 um, while the gap 19 may be on the order of <10,000 Angstroms (Å).

In some implementations, each pixel of the IMOD, whether in the actuated or relaxed state, is essentially a capacitor formed by the fixed and moving reflective layers. When no voltage is applied, the movable reflective layer 14a remains in a mechanically relaxed state, as illustrated by the pixel 12 on the left in FIG. 1, with the gap 19 between the movable reflective layer 14 and optical stack 16. However, when a potential difference, e.g., voltage, is applied to at least one of a selected row and column, the capacitor formed at the intersection of the row and column electrodes at the corresponding pixel becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated pixel 12 on the right in FIG. 1. The behavior is the same regardless of the polarity of the applied potential difference. Though a series of pixels in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

FIG. 2 shows an example of a system block diagram illustrating an electronic device incorporating a 3×3 interferometric modulator display. The electronic device includes a processor 21 that may be configured to execute one or more software modules. In addition to executing an operating system, the processor 21 may be configured to execute one or more software applications, including a web browser, a telephone application, an email program, or any other software application.

The processor 21 can be configured to communicate with an array driver 22. The array driver 22 can include a row driver circuit 24 and a column driver circuit 26 that provide signals to, e.g., a display array or panel 30. The cross section of the IMOD display device illustrated in FIG. 1 is shown by the lines 1-1 in FIG. 2. Although FIG. 2 illustrates a 3×3 array of IMODs for the sake of clarity, the display array 30 may contain a very large number of IMODs, and may have a different number of IMODs in rows than in columns, and vice versa.

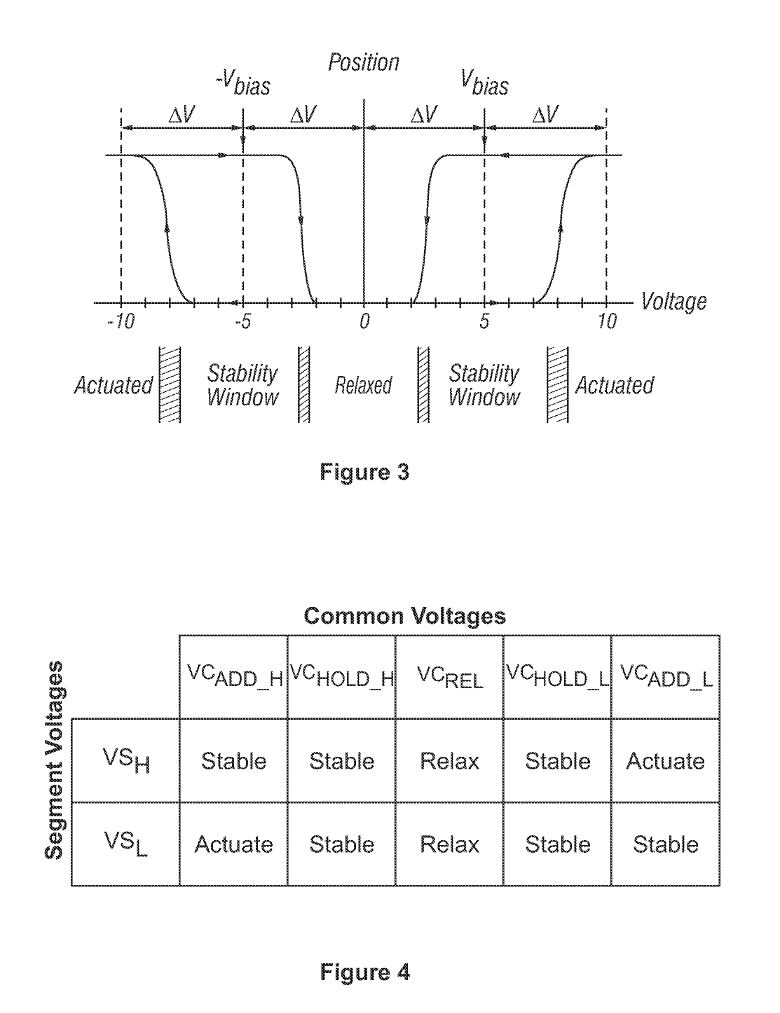

FIG. 3 shows an example of a diagram illustrating movable reflective layer position versus applied voltage for the interferometric modulator of FIG. 1. For MEMS interferometric modulators, the row/column (i.e., common/segment) write procedure may take advantage of a hysteresis property of these devices as illustrated in FIG. 3. An interferometric modulator may require, for example, about a 10-volt potential difference to cause the movable reflective layer, or mirror, to change from the relaxed state to the actuated state. When the voltage is reduced from that value, the movable reflective layer maintains its state as the voltage drops back below, e.g., 10-volts, however, the movable reflective layer does not relax completely until the voltage drops below 2-volts. Thus, a range of voltage, approximately 3 to 7-volts, as shown in FIG. 3, exists where there is a window of applied voltage within which the device is stable in either the relaxed or actuated state. This is referred to herein as the “hysteresis window” or “stability window.” For a display array 30 having the hysteresis characteristics of FIG. 3, the row/column write procedure can be designed to address one or more rows at a time, such that during the addressing of a given row, pixels in the addressed row that are to be actuated are exposed to a voltage difference of about 10-volts, and pixels that are to be relaxed are exposed to a voltage difference of near zero volts. After addressing, the pixels are exposed to a steady state or bias voltage difference of approximately 5-volts such that they remain in the previous strobing state. In this example, after being addressed, each pixel sees a potential difference within the “stability window” of about 3-7-volts. This hysteresis property feature enables the pixel design, e.g., illustrated in FIG. 1, to remain stable in either an actuated or relaxed pre-existing state under the same applied voltage conditions. Since each IMOD pixel, whether in the actuated or relaxed state, is essentially a capacitor formed by the fixed and moving reflective layers, this stable state can be held at a steady voltage within the hysteresis window without substantially consuming or losing power. Moreover, essentially little or no current flows into the IMOD pixel if the applied voltage potential remains substantially fixed.

In some implementations, a frame of an image may be created by applying data signals in the form of “segment” voltages along the set of column electrodes, in accordance with the desired change (if any) to the state of the pixels in a given row. Each row of the array can be addressed in turn, such that the frame is written one row at a time. To write the desired data to the pixels in a first row, segment voltages corresponding to the desired state of the pixels in the first row can be applied on the column electrodes, and a first row pulse in the form of a specific “common” voltage or signal can be applied to the first row electrode. The set of segment voltages can then be changed to correspond to the desired change (if any) to the state of the pixels in the second row, and a second common voltage can be applied to the second row electrode. In some implementations, the pixels in the first row are unaffected by the change in the segment voltages applied along the column electrodes, and remain in the state they were set to during the first common voltage row pulse. This process may be repeated for the entire series of rows, or alternatively, columns, in a sequential fashion to produce the image frame. The frames can be refreshed and/or updated with new image data by continually repeating this process at some desired number of frames per second.

The combination of segment and common signals applied across each pixel (that is, the potential difference across each pixel) determines the resulting state of each pixel. FIG. 4 shows an example of a table illustrating various states of an interferometric modulator when various common and segment voltages are applied. As will be readily understood by one having ordinary skill in the art, the “segment” voltages can be applied to either the column electrodes or the row electrodes, and the “common” voltages can be applied to the other of the column electrodes or the row electrodes.

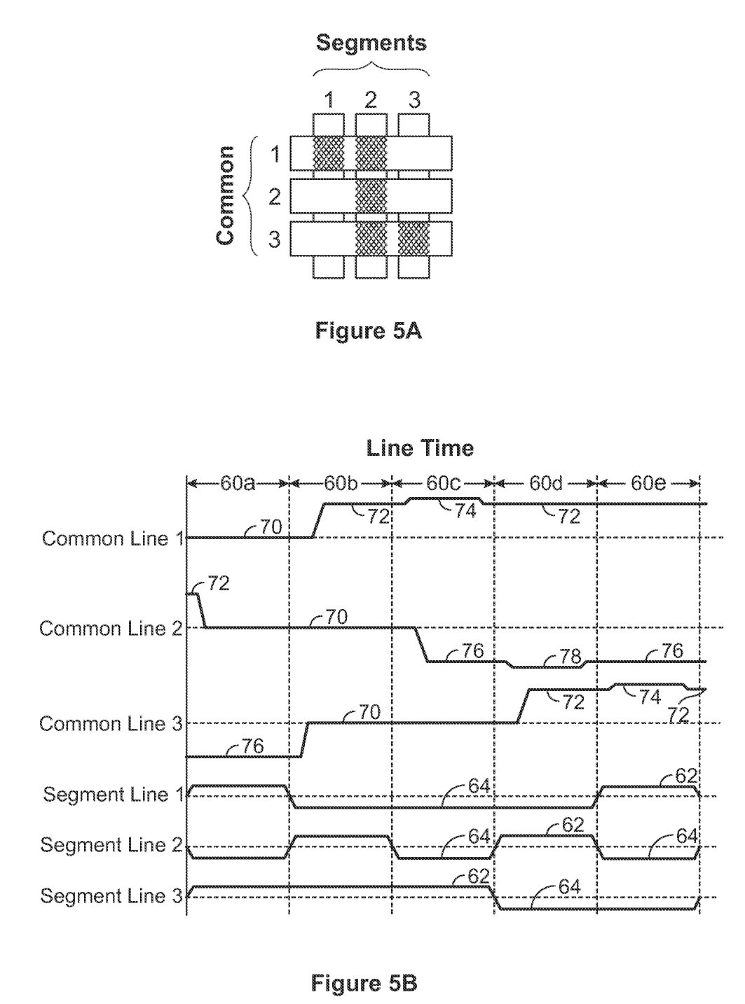

As illustrated in FIG. 4 (as well as in the timing diagram shown in FIG. 5B), when a release voltage VC_{REL} is applied along a common line, all interferometric modulator elements along the common line will be placed in a relaxed state, alternatively referred to as a released or unactuated state, regardless of the voltage applied along the segment lines, i.e., high segment voltage VS_{H} and low segment voltage VS_{L}. In particular, when the release voltage VC_{REL} is applied along a common line, the potential voltage across the modulator (alternatively referred to as a pixel voltage) is within the relaxation window (see FIG. 3, also referred to as a release window) both when the high segment voltage VS_{H} and the low segment voltage VS_{L} are applied along the corresponding segment line for that pixel.

When a hold voltage is applied on a common line, such as a high hold voltage VC_{HOLD}_{_{—}}_{H} or a low hold voltage V_{HOLD}_{_{—}}_{L}, the state of the interferometric modulator will remain constant. For example, a relaxed IMOD will remain in a relaxed position, and an actuated IMOD will remain in an actuated position. The hold voltages can be selected such that the pixel voltage will remain within a stability window both when the high segment voltage VS_{H} and the low segment voltage VS_{L} are applied along the corresponding segment line. Thus, the segment voltage swing, i.e., the difference between the high VS_{H} and low segment voltage VS_{L}, is less than the width of either the positive or the negative stability window.

When an addressing, or actuation, voltage is applied on a common line, such as a high addressing voltage VC_{ADD}_{_{—}}_{H} or a low addressing voltage VC_{ADD}_{_{—}}_{L}, data can be selectively written to the modulators along that line by application of segment voltages along the respective segment lines. The segment voltages may be selected such that actuation is dependent upon the segment voltage applied. When an addressing voltage is applied along a common line, application of one segment voltage will result in a pixel voltage within a stability window, causing the pixel to remain unactuated. In contrast, application of the other segment voltage will result in a pixel voltage beyond the stability window, resulting in actuation of the pixel. The particular segment voltage which causes actuation can vary depending upon which addressing voltage is used. In some implementations, when the high addressing voltage VC_{ADD}_{_{—}}_{H} is applied along the common line, application of the high segment voltage VS_{H} can cause a modulator to remain in its current position, while application of the low segment voltage VS_{L} can cause actuation of the modulator. As a corollary, the effect of the segment voltages can be the opposite when a low addressing voltage VC_{ADD}_{_{—}}_{L} is applied, with high segment voltage VS_{H} causing actuation of the modulator, and low segment voltage VS_{L} having no effect (i.e., remaining stable) on the state of the modulator.

In some implementations, hold voltages, address voltages, and segment voltages may be used which always produce the same polarity potential difference across the modulators. In some other implementations, signals can be used which alternate the polarity of the potential difference of the modulators. Alternation of the polarity across the modulators (that is, alternation of the polarity of write procedures) may reduce or inhibit charge accumulation which could occur after repeated write operations of a single polarity.

FIG. 5A shows an example of a diagram illustrating a frame of display data in the 3×3 interferometric modulator display of FIG. 2. FIG. 5B shows an example of a timing diagram for common and segment signals that may be used to write the frame of display data illustrated in FIG. 5A. The signals can be applied to the, e.g., 3×3 array of FIG. 2, which will ultimately result in the line time 60e display arrangement illustrated in FIG. 5A. The actuated modulators in FIG. 5A are in a dark-state, i.e., where a substantial portion of the reflected light is outside of the visible spectrum so as to result in a dark appearance to, e.g., a viewer. Prior to writing the frame illustrated in FIG. 5A, the pixels can be in any state, but the write procedure illustrated in the timing diagram of FIG. 5B presumes that each modulator has been released and resides in an unactuated state before the first line time 60a.

During the first line time 60a: a release voltage 70 is applied on common line 1; the voltage applied on common line 2 begins at a high hold voltage 72 and moves to a release voltage 70; and a low hold voltage 76 is applied along common line 3. Thus, the modulators (common 1, segment 1), (1,2) and (1,3) along common line 1 remain in a relaxed, or unactuated, state for the duration of the first line time 60a, the modulators (2,1), (2,2) and (2,3) along common line 2 will move to a relaxed state, and the modulators (3,1), (3,2) and (3,3) along common line 3 will remain in their previous state. With reference to FIG. 4, the segment voltages applied along segment lines 1, 2 and 3 will have no effect on the state of the interferometric modulators, as none of common lines 1, 2 or 3 are being exposed to voltage levels causing actuation during line time 60a (i.e., VC_{REL}-relax and VC_{HOLD}_{_{—}}_{L}-stable).

During the second line time 60b, the voltage on common line 1 moves to a high hold voltage 72, and all modulators along common line 1 remain in a relaxed state regardless of the segment voltage applied because no addressing, or actuation, voltage was applied on the common line 1. The modulators along common line 2 remain in a relaxed state due to the application of the release voltage 70, and the modulators (3,1), (3,2) and (3,3) along common line 3 will relax when the voltage along common line 3 moves to a release voltage 70.

During the third line time 60c, common line 1 is addressed by applying a high address voltage 74 on common line 1. Because a low segment voltage 64 is applied along segment lines 1 and 2 during the application of this address voltage, the pixel voltage across modulators (1,1) and (1,2) is greater than the high end of the positive stability window (i.e., the voltage differential exceeded a predefined threshold) of the modulators, and the modulators (1,1) and (1,2) are actuated. Conversely, because a high segment voltage 62 is applied along segment line 3, the pixel voltage across modulator (1,3) is less than that of modulators (1,1) and (1,2), and remains within the positive stability window of the modulator; modulator (1,3) thus remains relaxed. Also during line time 60c, the voltage along common line 2 decreases to a low hold voltage 76, and the voltage along common line 3 remains at a release voltage 70, leaving the modulators along common lines 2 and 3 in a relaxed position.

During the fourth line time 60d, the voltage on common line 1 returns to a high hold voltage 72, leaving the modulators along common line 1 in their respective addressed states. The voltage on common line 2 is decreased to a low address voltage 78. Because a high segment voltage 62 is applied along segment line 2, the pixel voltage across modulator (2,2) is below the lower end of the negative stability window of the modulator, causing the modulator (2,2) to actuate. Conversely, because a low segment voltage 64 is applied along segment lines 1 and 3, the modulators (2,1) and (2,3) remain in a relaxed position. The voltage on common line 3 increases to a high hold voltage 72, leaving the modulators along common line 3 in a relaxed state.

Finally, during the fifth line time 60e, the voltage on common line 1 remains at high hold voltage 72, and the voltage on common line 2 remains at a low hold voltage 76, leaving the modulators along common lines 1 and 2 in their respective addressed states. The voltage on common line 3 increases to a high address voltage 74 to address the modulators along common line 3. As a low segment voltage 64 is applied on segment lines 2 and 3, the modulators (3,2) and (3,3) actuate, while the high segment voltage 62 applied along segment line 1 causes modulator (3,1) to remain in a relaxed position. Thus, at the end of the fifth line time 60e, the 3×3 pixel array is in the state shown in FIG. 5A, and will remain in that state as long as the hold voltages are applied along the common lines, regardless of variations in the segment voltage which may occur when modulators along other common lines (not shown) are being addressed.

In the timing diagram of FIG. 5B, a given write procedure (i.e., line times 60a-60e) can include the use of either high hold and address voltages, or low hold and address voltages. Once the write procedure has been completed for a given common line (and the common voltage is set to the hold voltage having the same polarity as the actuation voltage), the pixel voltage remains within a given stability window, and does not pass through the relaxation window until a release voltage is applied on that common line. Furthermore, as each modulator is released as part of the write procedure prior to addressing the modulator, the actuation time of a modulator, rather than the release time, may determine the necessary line time. Specifically, in implementations in which the release time of a modulator is greater than the actuation time, the release voltage may be applied for longer than a single line time, as depicted in FIG. 5B. In some other implementations, voltages applied along common lines or segment lines may vary to account for variations in the actuation and release voltages of different modulators, such as modulators of different colors.

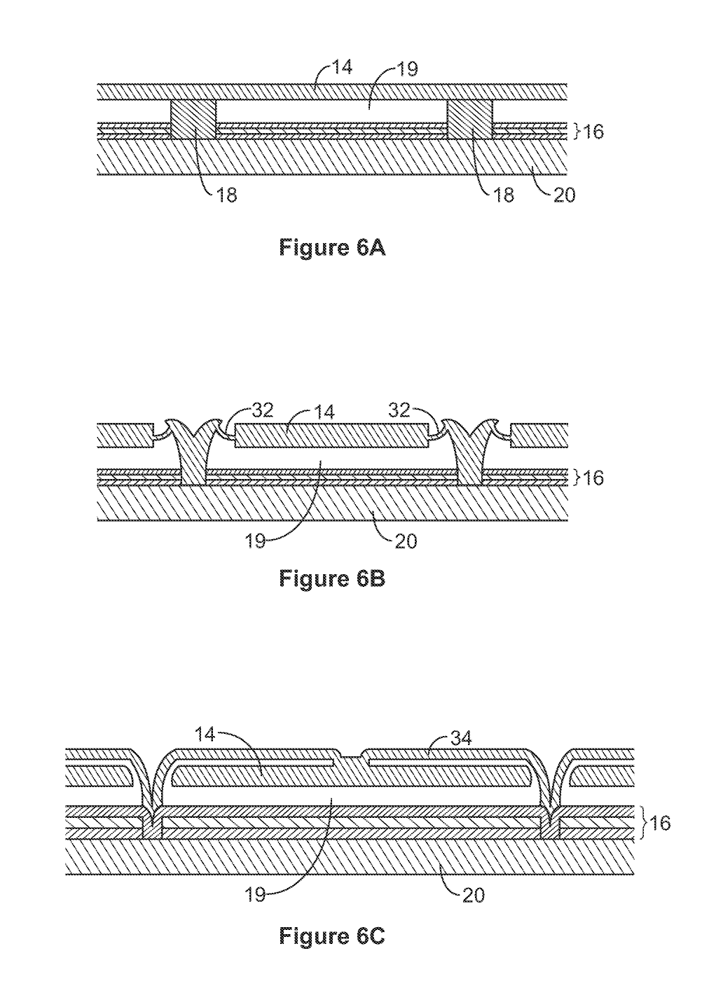

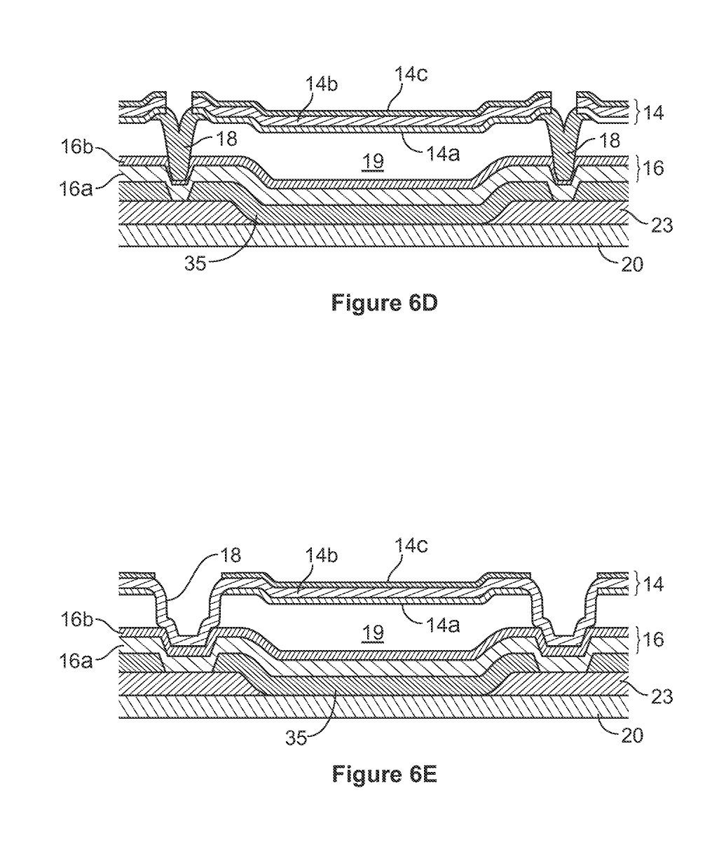

The details of the structure of interferometric modulators that operate in accordance with the principles set forth above may vary widely. For example, FIGS. 6A-6E show examples of cross-sections of varying implementations of interferometric modulators, including the movable reflective layer 14 and its supporting structures. FIG. 6A shows an example of a partial cross-section of the interferometric modulator display of FIG. 1, where a strip of metal material, i.e., the movable reflective layer 14 is deposited on supports 18 extending orthogonally from the substrate 20. In FIG. 6B, the movable reflective layer 14 of each IMOD is generally square or rectangular in shape and attached to supports at or near the corners, on tethers 32. In FIG. 6C, the movable reflective layer 14 is generally square or rectangular in shape and suspended from a deformable layer 34, which may include a flexible metal. The deformable layer 34 can connect, directly or indirectly, to the substrate 20 around the perimeter of the movable reflective layer 14. These connections are herein referred to as support posts. The implementation shown in FIG. 6C has additional benefits deriving from the decoupling of the optical functions of the movable reflective layer 14 from its mechanical functions, which are carried out by the deformable layer 34. This decoupling allows the structural design and materials used for the reflective layer 14 and those used for the deformable layer 34 to be optimized independently of one another.

FIG. 6D shows another example of an IMOD, where the movable reflective layer 14 includes a reflective sub-layer 14a. The movable reflective layer 14 rests on a support structure, such as support posts 18. The support posts 18 provide separation of the movable reflective layer 14 from the lower stationary electrode (i.e., part of the optical stack 16 in the illustrated IMOD) so that a gap 19 is formed between the movable reflective layer 14 and the optical stack 16, for example when the movable reflective layer 14 is in a relaxed position. The movable reflective layer 14 also can include a conductive layer 14c, which may be configured to serve as an electrode, and a support layer 14b. In this example, the conductive layer 14c is disposed on one side of the support layer 14b, distal from the substrate 20, and the reflective sub-layer 14a is disposed on the other side of the support layer 14b, proximal to the substrate 20. In some implementations, the reflective sub-layer 14a can be conductive and can be disposed between the support layer 14b and the optical stack 16. The support layer 14b can include one or more layers of a dielectric material, for example, silicon oxynitride (SiON) or silicon dioxide (SiO₂). In some implementations, the support layer 14b can be a stack of layers, such as, for example, a SiO₂/SiON/SiO₂ tri-layer stack. Either or both of the reflective sub-layer 14a and the conductive layer 14c can include, e.g., an Al alloy with about 0.5% Cu, or another reflective metallic material. Employing conductive layers 14a, 14c above and below the dielectric support layer 14b can balance stresses and provide enhanced conduction. In some implementations, the reflective sub-layer 14a and the conductive layer 14c can be formed of different materials for a variety of design purposes, such as achieving specific stress profiles within the movable reflective layer 14.

As illustrated in FIG. 6D, some implementations also can include a black mask structure 23. The black mask structure 23 can be formed in optically inactive regions (e.g., between pixels or under posts 18) to absorb ambient or stray light. The black mask structure 23 also can improve the optical properties of a display device by inhibiting light from being reflected from or transmitted through inactive portions of the display, thereby increasing the contrast ratio. Additionally, the black mask structure 23 can be conductive and be configured to function as an electrical bussing layer. In some implementations, the row electrodes can be connected to the black mask structure 23 to reduce the resistance of the connected row electrode. The black mask structure 23 can be formed using a variety of methods, including deposition and patterning techniques. The black mask structure 23 can include one or more layers. For example, in some implementations, the black mask structure 23 includes a molybdenum-chromium (MoCr) layer that serves as an optical absorber, a SiO₂ layer, and an aluminum alloy that serves as a reflector and a bussing layer, with a thickness in the range of about 30-80 Å, 500-1000 Å, and 500-6000 Å, respectively. The one or more layers can be patterned using a variety of techniques, including photolithography and dry etching, including, for example, CF₄ and/or O₂ for the MoCr and SiO₂ layers and Cl₂ and/or BCl₃ for the aluminum alloy layer. In some implementations, the black mask 23 can be an etalon or interferometric stack structure. In such interferometric stack black mask structures 23, the conductive absorbers can be used to transmit or bus signals between lower, stationary electrodes in the optical stack 16 of each row or column. In some implementations, a spacer layer 35 can serve to generally electrically isolate the absorber layer 16a from the conductive layers in the black mask 23.

FIG. 6E shows another example of an IMOD, where the movable reflective layer 14 is self supporting. In contrast with FIG. 6D, the implementation of FIG. 6E does not include support posts 18. Instead, the movable reflective layer 14 contacts the underlying optical stack 16 at multiple locations, and the curvature of the movable reflective layer 14 provides sufficient support that the movable reflective layer 14 returns to the unactuated position of FIG. 6E when the voltage across the interferometric modulator is insufficient to cause actuation. The optical stack 16, which may contain a plurality of several different layers, is shown here for clarity including an optical absorber 16a, and a dielectric 16b. In some implementations, the optical absorber 16a may serve both as a fixed electrode and as a partially reflective layer.

In implementations such as those shown in FIGS. 6A-6E, the IMODs function as direct-view devices, in which images are viewed from the front side of the transparent substrate 20, i.e., the side opposite to that upon which the modulator is arranged. In these implementations, the back portions of the device (that is, any portion of the display device behind the movable reflective layer 14, including, for example, the deformable layer 34 illustrated in FIG. 6C) can be configured and operated upon without impacting or negatively affecting the image quality of the display device, because the reflective layer 14 optically shields those portions of the device. For example, in some implementations a bus structure (not illustrated) can be included behind the movable reflective layer 14 which provides the ability to separate the optical properties of the modulator from the electromechanical properties of the modulator, such as voltage addressing and the movements that result from such addressing. Additionally, the implementations of FIGS. 6A-6E can simplify processing, such as, e.g., patterning.

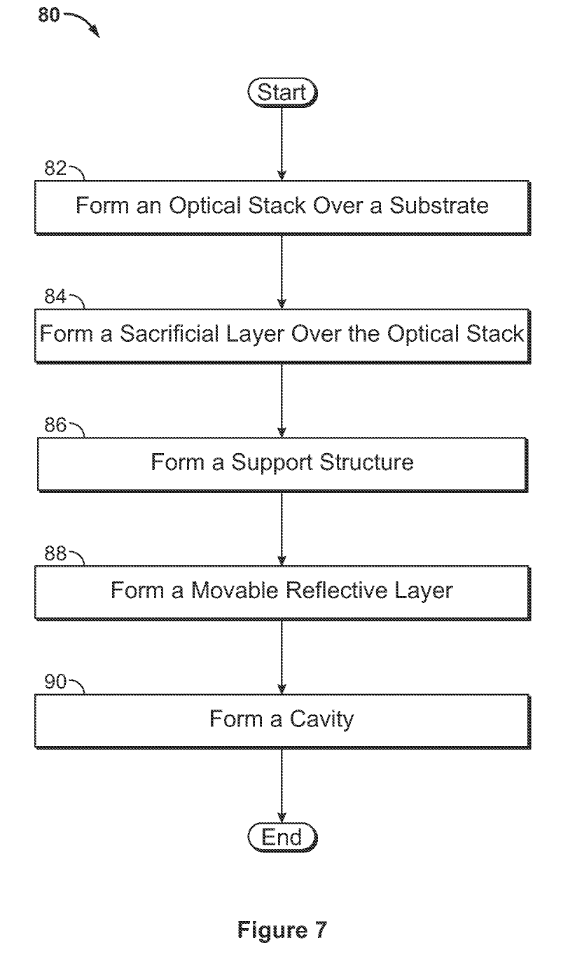

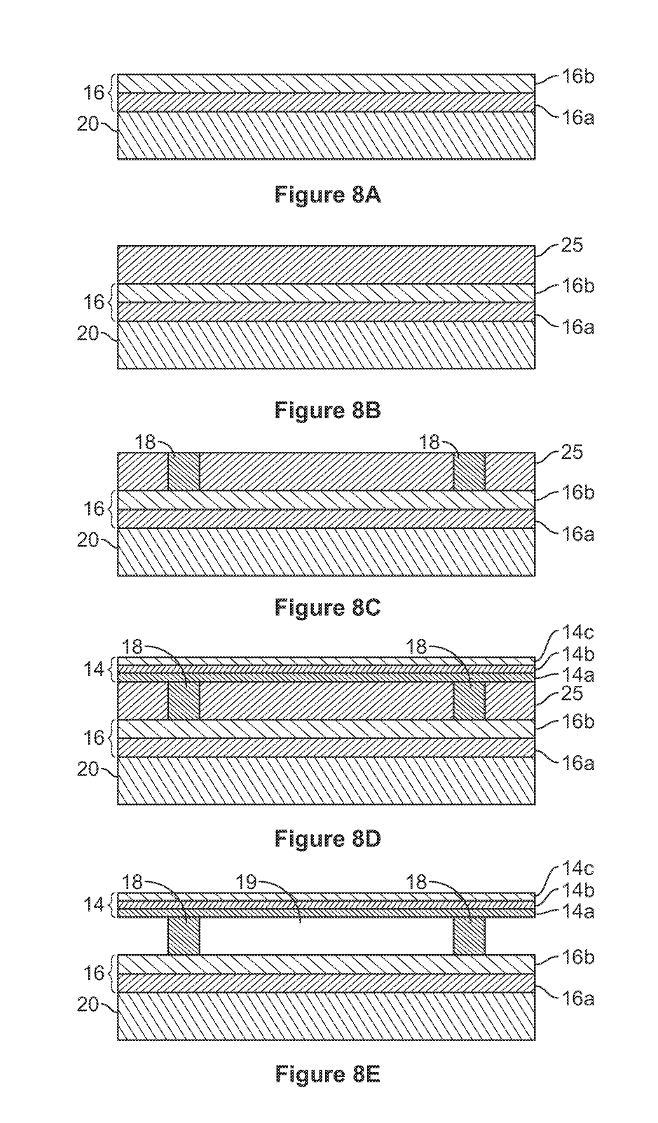

FIG. 7 shows an example of a flow diagram illustrating a manufacturing process 80 for an interferometric modulator, and FIGS. 8A-8E show examples of cross-sectional schematic illustrations of corresponding stages of such a manufacturing process 80. In some implementations, the manufacturing process 80 can be implemented to manufacture, e.g., interferometric modulators of the general type illustrated in FIGS. 1 and 6, in addition to other blocks not shown in FIG. 7. With reference to FIGS. 1, 6 and 7, the process 80 begins at block 82 with the formation of the optical stack 16 over the substrate 20. FIG. 8A illustrates such an optical stack 16 formed over the substrate 20. The substrate 20 may be a transparent substrate such as glass or plastic, it may be flexible or relatively stiff and unbending, and may have been subjected to prior preparation processes, e.g., cleaning, to facilitate efficient formation of the optical stack 16. As discussed above, the optical stack 16 can be electrically conductive, partially transparent and partially reflective and may be fabricated, for example, by depositing one or more layers having the desired properties onto the transparent substrate 20. In FIG. 8A, the optical stack 16 includes a multilayer structure having sub-layers 16a and 16b, although more or fewer sub-layers may be included in some other implementations. In some implementations, one of the sub-layers 16a, 16b can be configured with both optically absorptive and conductive properties, such as the combined conductor/absorber sub-layer 16a. Additionally, one or more of the sub-layers 16a, 16b can be patterned into parallel strips, and may form row electrodes in a display device. Such patterning can be performed by a masking and etching process or another suitable process known in the art. In some implementations, one of the sub-layers 16a, 16b can be an insulating or dielectric layer, such as sub-layer 16b that is deposited over one or more metal layers (e.g., one or more reflective and/or conductive layers). In addition, the optical stack 16 can be patterned into individual and parallel strips that form the rows of the display.

The process 80 continues at block 84 with the formation of a sacrificial layer 25 over the optical stack 16. The sacrificial layer 25 is later removed (e.g., at block 90) to form the cavity 19 and thus the sacrificial layer 25 is not shown in the resulting interferometric modulators 12 illustrated in FIG. 1. FIG. 8B illustrates a partially fabricated device including a sacrificial layer 25 formed over the optical stack 16. The formation of the sacrificial layer 25 over the optical stack 16 may include deposition of a xenon difluoride (XeF₂)-etchable material such as molybdenum (Mo) or amorphous silicon (Si), in a thickness selected to provide, after subsequent removal, a gap or cavity 19 (see also FIGS. 1 and 8E) having a desired design size. Deposition of the sacrificial material may be carried out using deposition techniques such as physical vapor deposition (PVD, e.g., sputtering), plasma-enhanced chemical vapor deposition (PECVD), thermal chemical vapor deposition (thermal CVD), or spin-coating.

The process 80 continues at block 86 with the formation of a support structure e.g., a post 18 as illustrated in FIGS. 1, 6 and 8C. The formation of the post 18 may include patterning the sacrificial layer 25 to form a support structure aperture, then depositing a material (e.g., a polymer or an inorganic material, e.g., silicon oxide) into the aperture to form the post 18, using a deposition method such as PVD, PECVD, thermal CVD, or spin-coating. In some implementations, the support structure aperture formed in the sacrificial layer can extend through both the sacrificial layer 25 and the optical stack 16 to the underlying substrate 20, so that the lower end of the post 18 contacts the substrate 20 as illustrated in FIG. 6A. Alternatively, as depicted in FIG. 8C, the aperture formed in the sacrificial layer 25 can extend through the sacrificial layer 25, but not through the optical stack 16. For example, FIG. 8E illustrates the lower ends of the support posts 18 in contact with an upper surface of the optical stack 16. The post 18, or other support structures, may be formed by depositing a layer of support structure material over the sacrificial layer 25 and patterning portions of the support structure material located away from apertures in the sacrificial layer 25. The support structures may be located within the apertures, as illustrated in FIG. 8C, but also can, at least partially, extend over a portion of the sacrificial layer 25. As noted above, the patterning of the sacrificial layer 25 and/or the support posts 18 can be performed by a patterning and etching process, but also may be performed by alternative etching methods.

The process 80 continues at block 88 with the formation of a movable reflective layer or membrane such as the movable reflective layer 14 illustrated in FIGS. 1, 6 and 8D. The movable reflective layer 14 may be formed by employing one or more deposition steps, e.g., reflective layer (e.g., aluminum, aluminum alloy) deposition, along with one or more patterning, masking, and/or etching steps. The movable reflective layer 14 can be electrically conductive, and referred to as an electrically conductive layer. In some implementations, the movable reflective layer 14 may include a plurality of sub-layers 14a, 14b, 14c as shown in FIG. 8D. In some implementations, one or more of the sub-layers, such as sub-layers 14a, 14c, may include highly reflective sub-layers selected for their optical properties, and another sub-layer 14b may include a mechanical sub-layer selected for its mechanical properties. Since the sacrificial layer 25 is still present in the partially fabricated interferometric modulator formed at block 88, the movable reflective layer 14 is typically not movable at this stage. A partially fabricated IMOD that contains a sacrificial layer 25 may also be referred to herein as an “unreleased” IMOD. As described above in connection with FIG. 1, the movable reflective layer 14 can be patterned into individual and parallel strips that form the columns of the display.

The process 80 continues at block 90 with the formation of a cavity, e.g., cavity 19 as illustrated in FIGS. 1, 6 and 8E. The cavity 19 may be formed by exposing the sacrificial material 25 (deposited at block 84) to an etchant. For example, an etchable sacrificial material such as Mo or amorphous Si may be removed by dry chemical etching, e.g., by exposing the sacrificial layer 25 to a gaseous or vaporous etchant, such as vapors derived from solid XeF₂ for a period of time that is effective to remove the desired amount of material, typically selectively removed relative to the structures surrounding the cavity 19. Other etching methods, e.g. wet etching and/or plasma etching, also may be used. Since the sacrificial layer 25 is removed during block 90, the movable reflective layer 14 is typically movable after this stage. After removal of the sacrificial material 25, the resulting fully or partially fabricated IMOD may be referred to herein as a “released” IMOD.

As discussed above, sensing devices can be disposed over one or more displays, for example, the interferometric modulators described in reference to FIGS. 1-8E. In some implementations, a capacitive touch sensing device can be disposed over at least a portion of one or more MEMS devices, interferometric modulator devices, reflective display devices, and/or other display devices. As ambient light incident on the sensing device passes through, e.g., the sensor regions of these sensing devices at least twice before being reflected back to, e.g., a viewer, it is desirable to limit the amount of light that is absorbed and/or reflected by a sensing device overlying a reflective display. Sensing arrays disclosed herein can include transparent, semi-transparent, or non-transparent conductive rows and columns that at least partially define non-conductive and optically transparent volumes. These optically transparent volumes can allow light to pass therethrough with minimal absorption and/or reflection and the conductive rows and columns can be utilized by a sensing circuit to determine the location of a conductive object, e.g., a finger, that is proximal to the sensor region.

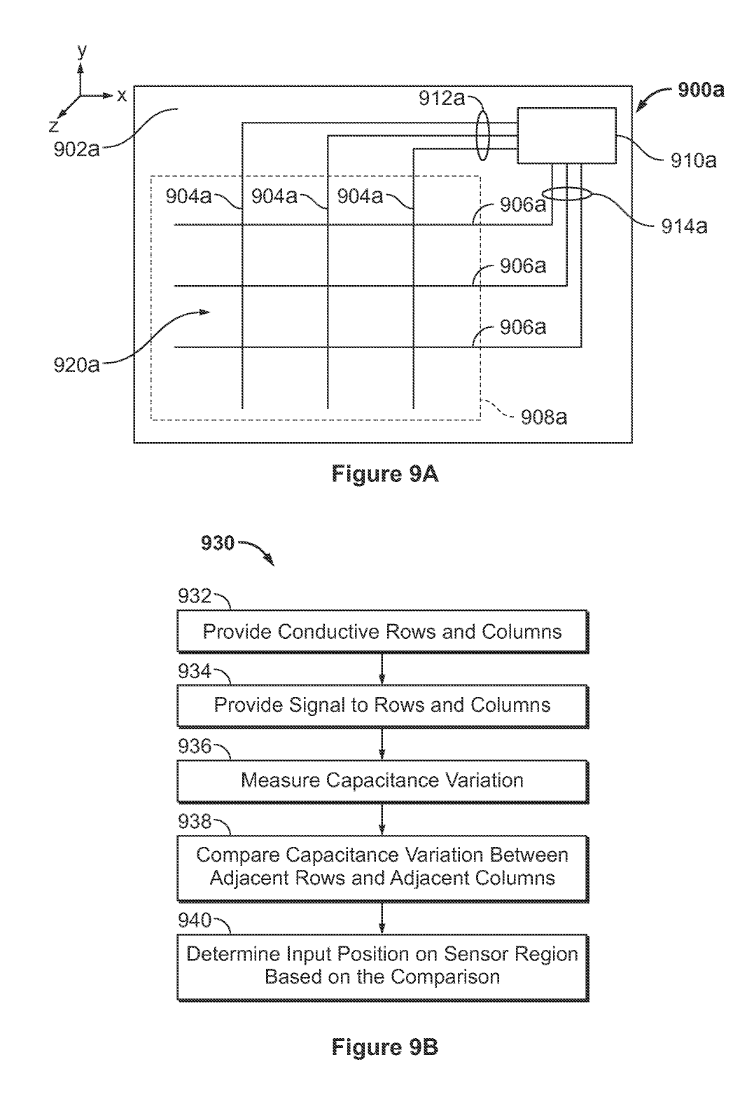

FIG. 9A shows a top side view of an example sensing device having a plurality of conductive rows and columns for detecting a presence of a conductive object over the sensor array. Though some of the conductive structures disclosed herein can be referred to as “rows” or “columns,” a person having ordinary skill in the art will readily understand that referring to one direction as a “row” and another as a “column” is arbitrary. Restated, in some orientations, the rows can be considered columns, and the columns considered to be rows. Furthermore, the conductive structures may be evenly arranged in orthogonal rows and columns (an “array”), or arranged in non-linear configurations, for example, having certain positional offsets with respect to one another (a “mosaic”). Thus, the conductive structures referred to as rows and columns need not be arranged orthogonally to one another, or disposed in an even distribution, in any instance, but may include arrangements having asymmetric shapes and unevenly distributed elements.

The sensing device 900 can be configured to determine the location of a conductive object, for example, a user's finger or a stylus, relative to the sensing device 900 and provide this location to an external circuit, for example, a computer or other electronic device. In one implementation, the sensing device 900 can be disposed over an underlying reflective display (not shown), for example, an interferometric display. In such an implementation, a viewer can observe at least a portion of the underlying reflective display through a sensor region 908 of the sensing device 900.

The sensing device 900 can include a substantially transparent cover substrate 902 having a set of conductive rows 906 and a set of conductive columns 904 disposed underneath the cover substrate 902. Details of the set of conductive rows 906 and the set of conductive columns 904 are not shown in FIG. 9A for clarity. The cover substrate 902 can include an insulating material, for example, glass. The conductive rows and columns 906, 904 define a sensor array 920 within the sensor region 908. The conductive rows and columns 906, 904 are electrically coupled to a sensing circuit 910 by conductive leads 912, 914. The sensing circuit 910 periodically applies a pulse signal to the individual conductive rows and columns 906, 904 and detects the capacitance between separate conductive rows and columns 906, 904 and/or between a conductive row or column and an arbitrary earth ground. The capacitance between a conductive row and a conductive column can be referred to as “mutual capacitance” and the capacitance between a conductive row or column and an arbitrary earth ground can be referred to as “self capacitance.” Positioning a conductive object near to an overlap between conductive rows and columns 906, 904 changes the local electrostatic field which reduces the mutual capacitance between conductive rows and columns 906, 904. The sensing circuit 910 can detect the presence of a conductive object that is located proximally (e.g., touching or disposed near) to an area of the sensor region 908 by periodically detecting the mutual and/or self capacitances of the conductive rows and columns 906, 904 and comparing the changes in capacitance from a default condition. Based on the patterning of the geometry of the conductive rows and columns 906, 904, the location of the conductive object relative to the sensing device 900 can be determined. This sensed location can be provided by the sensing circuit 910 to an external circuit, for example, to a circuit that controls an underlying reflective display.

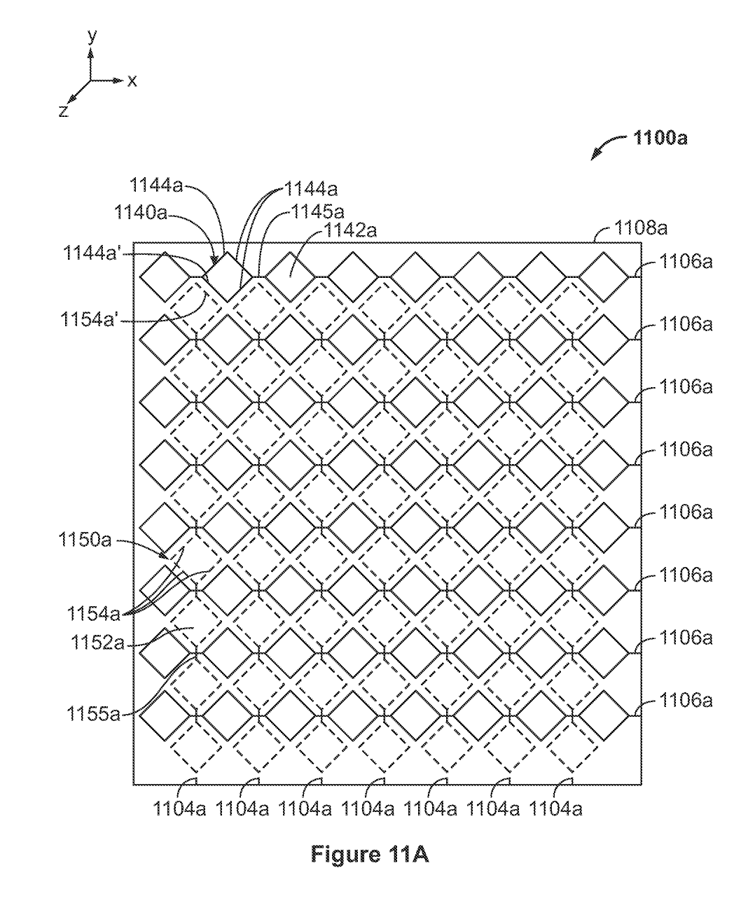

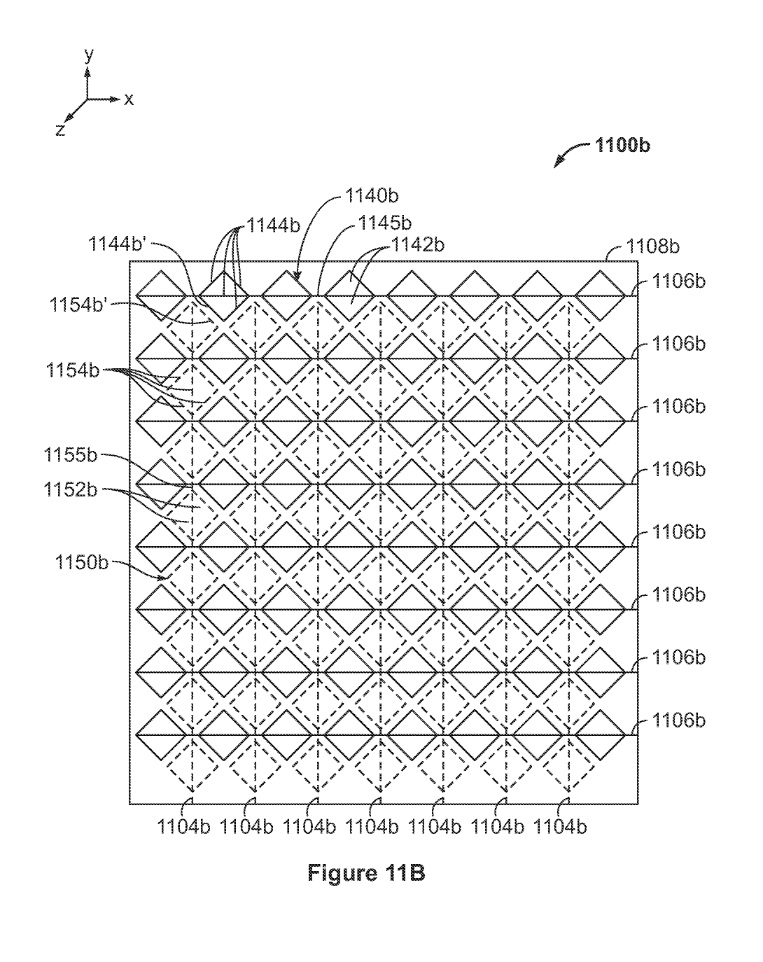

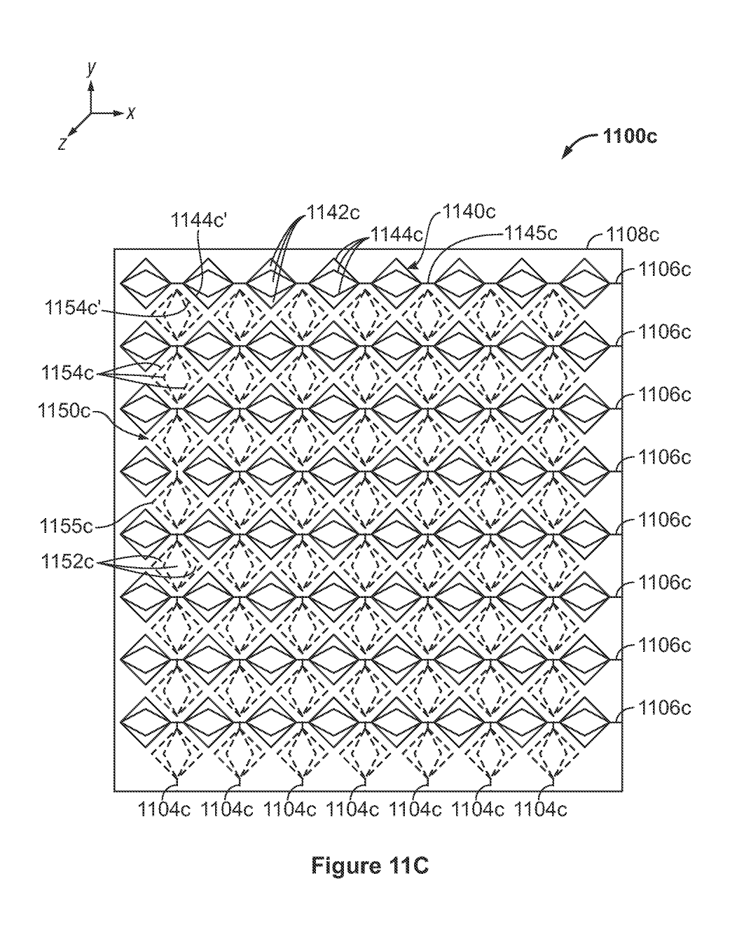

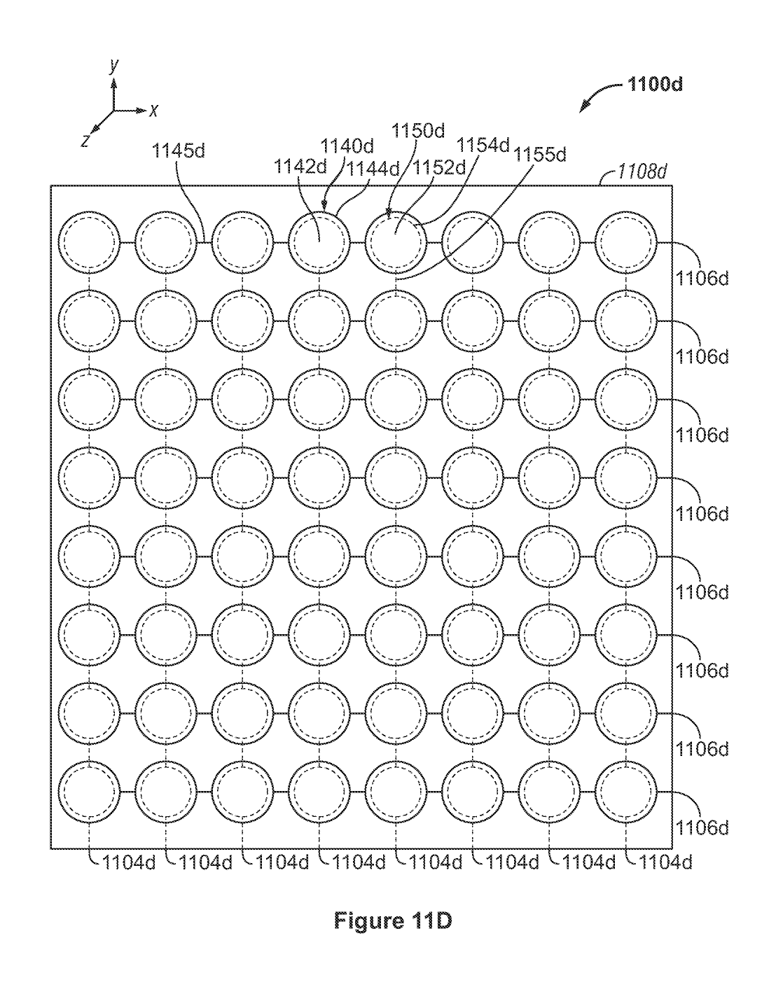

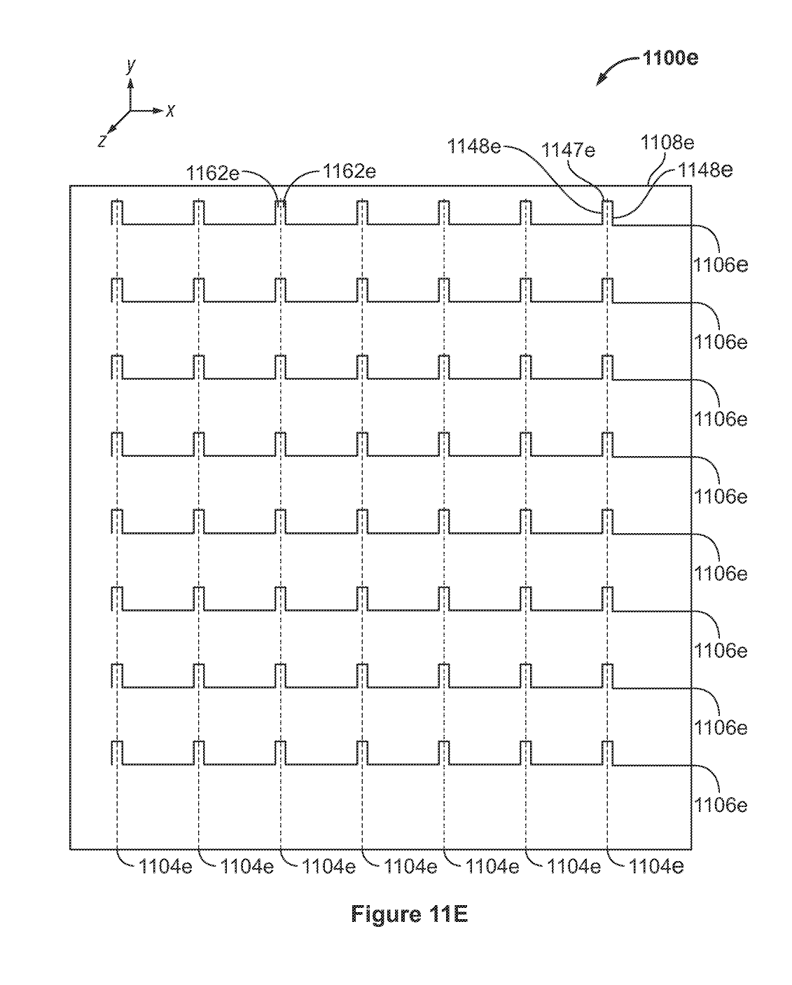

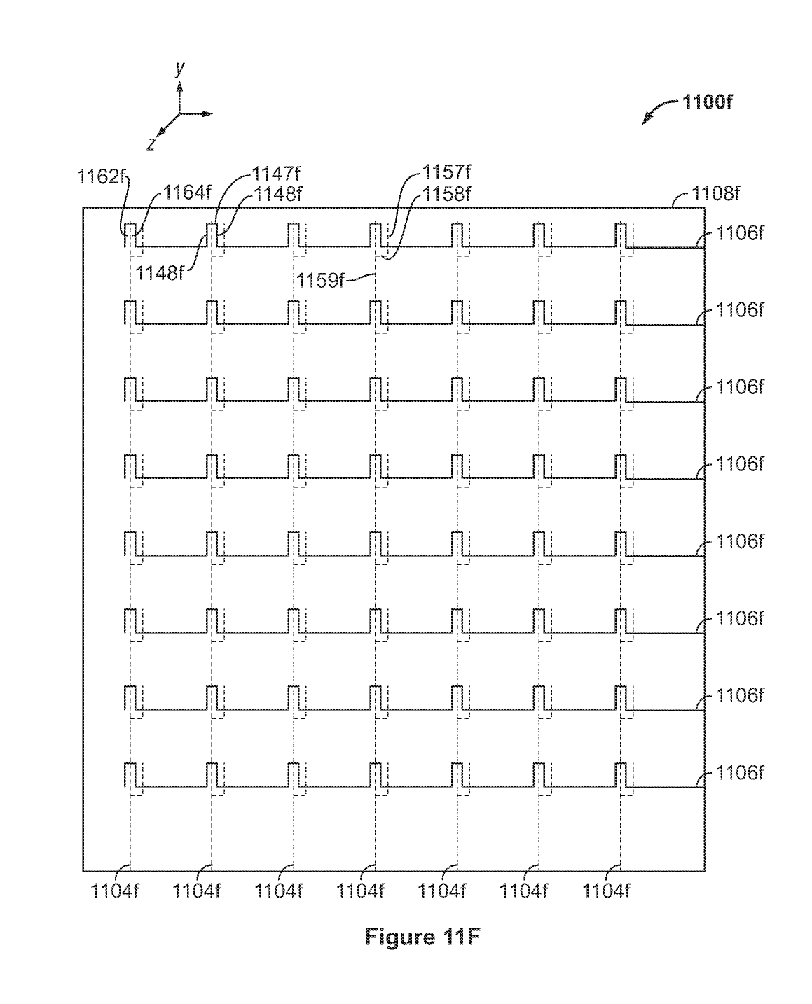

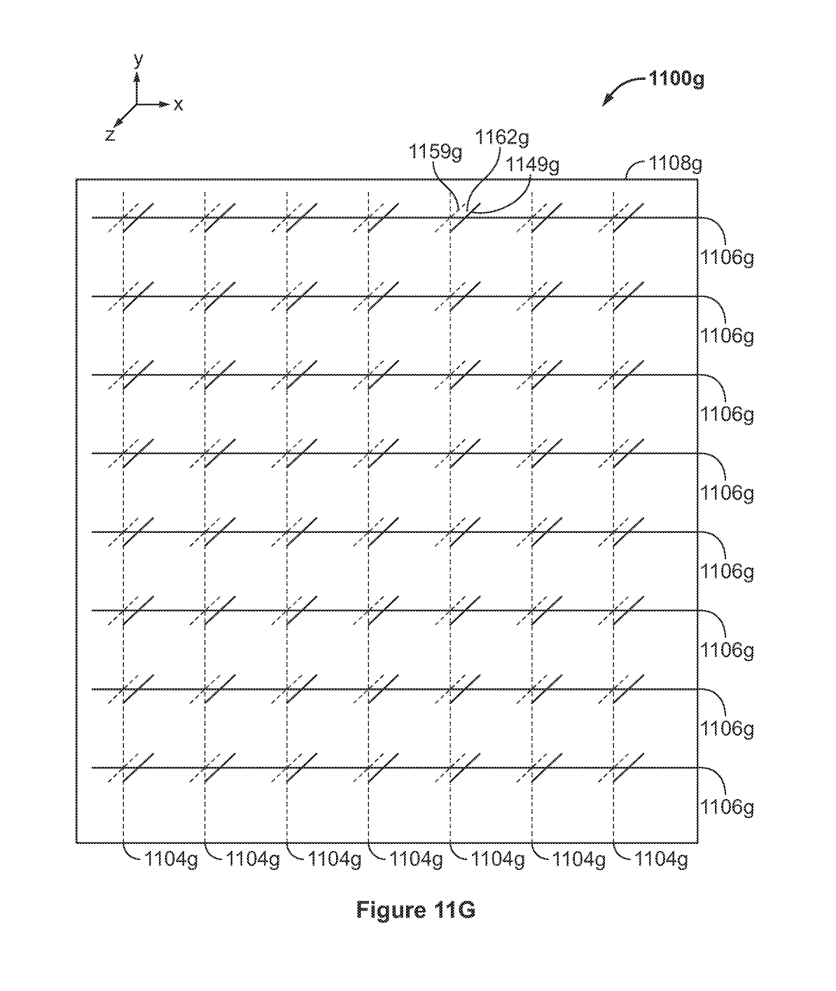

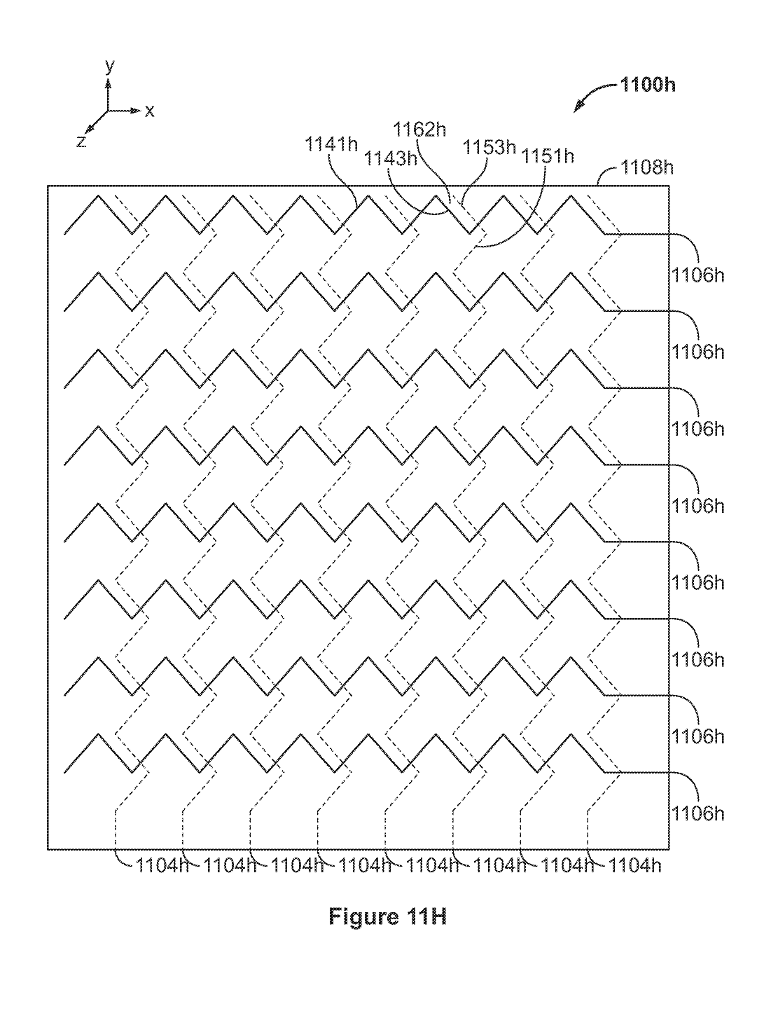

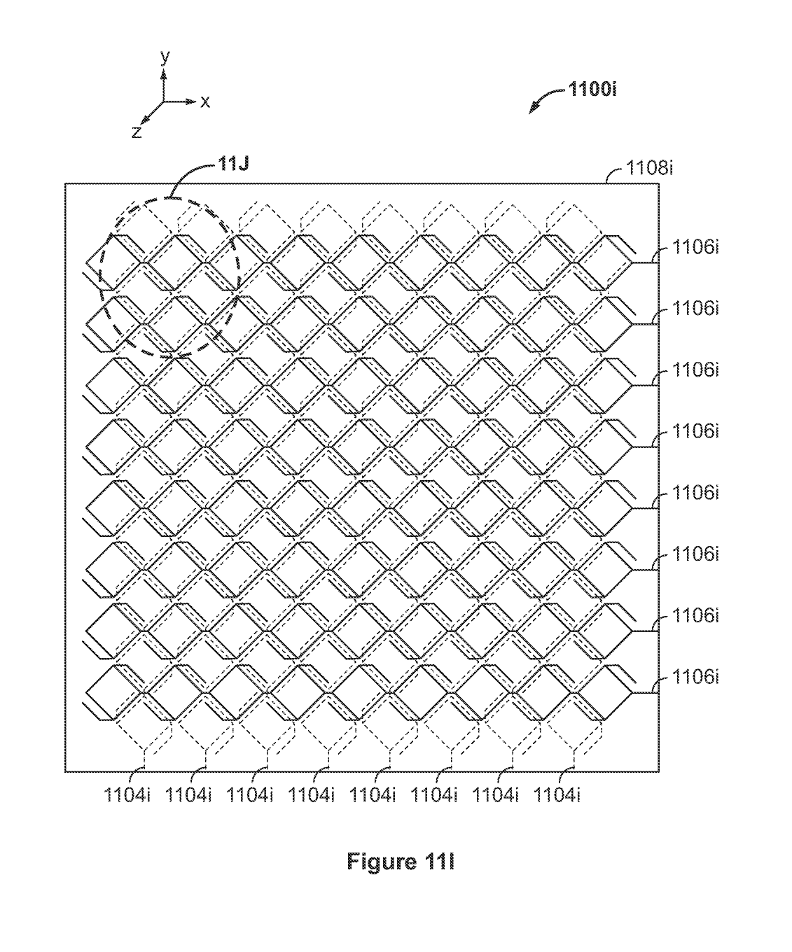

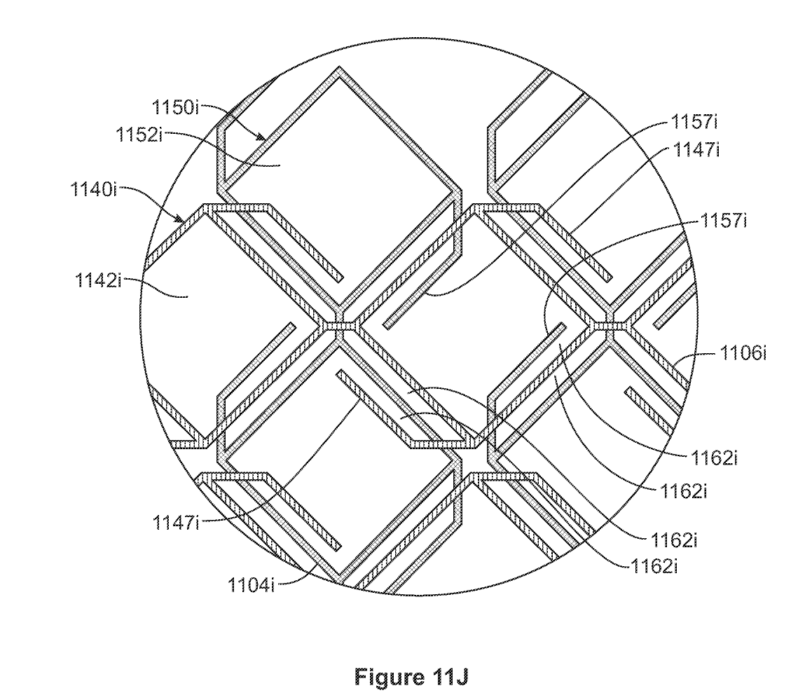

As discussed in further detail below with reference to FIGS. 11A-11I, in some implementations conductive rows and columns 906, 904 can include wire-frame geometries that are partially hollowed out to at least partially define one or more volumes of non-conductive and transparent material. These implementations have reduced self capacitance compared to non-hollowed out wire-frames and also have a higher mutual capacitance because of increased periphery regions. Reducing the self capacitance and increasing the mutual capacitance of a conductive row or column in a sensing device can improve the capability of the sensing device to detect the presence of an object, e.g., a finger, or a stylus.

FIG. 9B shows a flow diagram illustrating an example method of operating a sensing device. The method 930 can be used to operate various sensing devices, for example, the sensing device 900 of FIG. 9A. As shown at block 932, conductive rows and columns spaced apart from each other can be provided to form a sensor array within a sensor region. As discussed above, the sensor region can be disposed over an underlying display, for example, a reflective display. As shown at block 934, a signal can be provided to each conductive row and column by an external sensing circuit and the capacitance variation of each row and column can measured over time as shown at block 936. The sensing circuit can compare the periodic capacitance variation between adjacent rows and adjacent columns as shown at block 938. Each row can be associated with a coordinate position (e.g., a vertical position) on the sensor region and each column can be associated with another coordinate position (e.g., a horizontal position) on the sensor region such that the compared capacitance variation is used to determine a two-dimensional input position (e.g., a horizontal-vertical coordinate position) of a conductive object over the sensor region as shown at block 940.

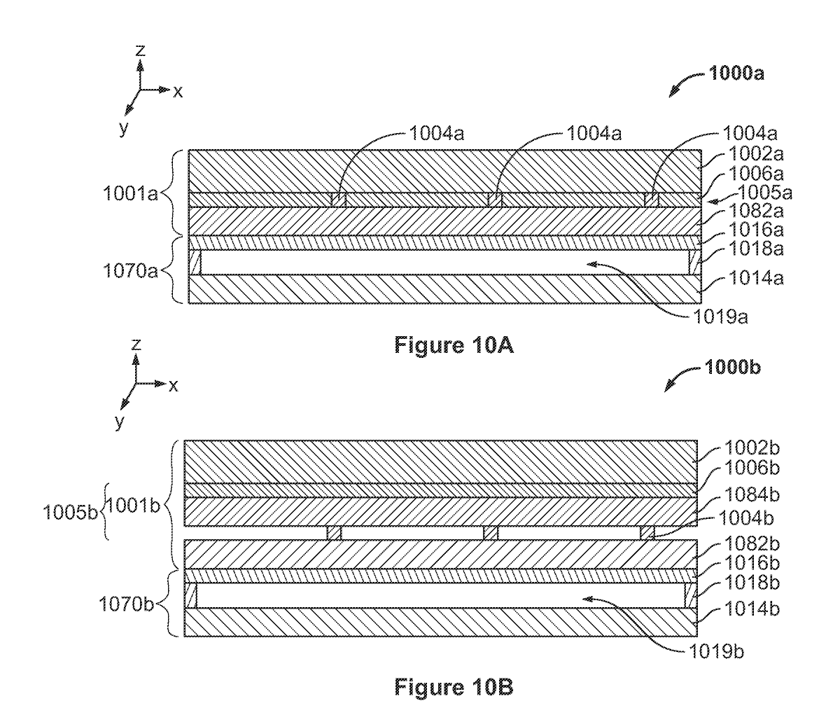

FIGS. 10A and 10B show cross-sections of two example implementations of sensing devices. FIG. 10A shows a cross-section of a display device 1000a including a sensing device 1001a disposed over an underlying interferometric display 1070a. As discussed above, the sensing devices disclosed herein can be disposed over other types of displays and/or objects that are not displays. The sensing device 1001a includes a cover layer 1002a disposed on a first side and an insulating layer 1082a disposed on an opposite side. In some implementations, the cover layer 1002a can be configured to protect components disposed below the cover layer 1002a and can have a thickness that is between about 0.02 mm and 1.5 mm. In other implementations, the cover layer 1002a can have a thickness that is less than 20 mm and as thin as about 0.5 μm. In some implementations, the insulating layer 1082a can include a non-conductive material and can be configured to electrically isolate the sensing device 1001a from the underlying interferometric display 1070a. The sensing device 1001a further includes a conductive row 1006a extending generally parallel to the x-axis (shown as left to right in the figure) and a set of conductive columns 1004a extending generally perpendicular to conductive row 1006a and generally parallel to the y-axis (shown as in and out of the plane of the figure). As used herein, the term “parallel” can refer to two or more lines that lie in the same plane but do not intersect. In some examples, parallel lines can extend straight relative to one another and in other examples, parallel lines can include one or more curvilinear segments that track curvilinear segments on the other parallel line(s). The conductive columns 1004a and conductive row 1006a can form a sensor array 1005a that can be electrically coupled with one or more sensing circuits (not shown) to form a sensing device as discussed above. Electrical vias through an insulating layer and crossover or cross-under segments (not shown) allow portions of conductive columns 1004a or conductive rows 1006a to be electrically connected to other portions of conductive columns 1004a or conductive rows 1006a, respectively, while avoiding electrical shorting between adjacent or overlapping conductive rows 1006a and conductive columns 1004a.

Still referring to FIG. 10A, the interferometric display 1070a is disposed underneath the sensor array 1005a such that light incident on the display device 1000a passes through the sensor array 1005a toward the interferometric display 1070a. The interferometric display 1070a includes an absorber layer 1016a (e.g., a partially reflective and partially transmissive layer) and a movable reflector layer 1014a that is offset from the absorber layer 1016a by one or more posts 1018a. An optical resonant cavity 1019a is disposed between the absorber layer 1016a and the movable reflector layer 1014a. As discussed above, with respect to the movable reflective layer described with reference to some of the FIGS. 1-8E, the movable reflector layer 1014a can be driven between at least two states to change the wavelength of light reflected from the display device 1000a. The brightness of the display device 1000a can correlate to the amount of light incident on the display device 1000a and the amount of light lost in passing through the sensor array 1005a. The conductive rows and columns 1006a, 1004a can at least partially define volumes of optically transparent and non-conductive material(s) as discussed below with reference to FIGS. 11A-11J. Accordingly, the sensing device 1001a can be configured to limit the loss of light that passes through the optically transparent and non-conductive volumes.

FIG. 10B schematically illustrates another implementation of a display device 1000b incorporating a sensing device 1001b disposed over an underlying interferometric display 1070b. In this implementation, the sensor array 1005b can include a second insulating layer 1084b disposed between a set of conductive rows 1006b and a set of conductive columns 1004b. The first and second insulating layers 1082b, 1084b can include any insulating or dielectric material configured to isolate the conductive rows and columns 1006b, 1004b from one another and from the absorber layer 1016b. The first and second insulating layers 1082b, 1084b can be optically transparent to allow light to pass therethrough without significant absorption. Additionally, the indices of refraction of the first and second insulating layers 1082b, 1084b can be selected to inhibit reflection of light that passes therethrough.

Turning now to FIGS. 11A-11I, top-side views of different implementations of example sensing arrays for use in sensing devices are shown. In each implementation, the sensing array 1100 is disposed within a sensor region 1108 and includes a set of conductive rows 1106 (denoted by solid lines) and a set of conductive columns 1104 (denoted by dashed lines). Each of the set of conductive rows 1106 includes a conductive material that extends generally in a first direction, for example, horizontally (e.g., parallel to the x-axis) and each of the set of conductive columns 1104 includes a conductive material that extends generally in a second direction, for example, vertically (e.g., parallel to the y-axis). In one implementation, each of the set of conductive rows 1106 extends generally perpendicular to each of the set of conductive columns 1104 such that portions of the set of conductive rows 1106 overlap portions of the set of conductive columns 1104. Each of the conductive rows and columns 1106, 1104 can be electrically coupled to one or more sensing circuits (not shown) by electrical leads (i.e., conductive leads 912, 914) as shown in FIG. 9A. The one or more sensing circuits can periodically apply signals to the conductive rows and columns 1106, 1104 and measure the variation in mutual capacitances and/or self capacitances over time to locate the presence and location of a conductive object disposed proximal to the sensor region 1108.

FIG. 11A schematically illustrates a first implementation of a sensing array 1100a including a set of conductive rows 1106a. Each of the set of conductive rows 1106a extends generally parallel to the x-axis of the sensing array 1100a. The sensing array 1100a also includes a set of conductive columns 1104a and each of the set of conductive columns 1104a extends generally parallel to the y-axis of the sensor array (e.g., generally perpendicular to the set of conductive rows 1106a) such that portions of the set of conductive columns 1104a overlap portions of the set of conductive rows 1106a.

The set of conductive rows 1106a and the set of conductive columns 1104a can include various conductive materials, for example, aluminum or molybdenum, capable of conducting an electrical signal applied by one or more sensing circuits. In some implementations, each of the set of conductive rows 1106a includes a plurality of conductive segments 1144a or members that are connected to one another to form a singular conductive row 1106a. Some of the conductive segments 1144a can define a sensing element 1140a and the sensing elements 1140a can be connected to each other by connecting segments 1145a that are electrically conductive. The sensing elements 1140a can form, or at least partially form, various shapes in a plane parallel to the x-y plane including, for example, squares, diamonds, polygons and curvilinear shapes. Each conductive segment 1144a, 1145a can have a width of between about 3 μm and about 20 μm such that the width is difficult to observe by a human observer viewing the sensing array 1100a from an appropriate distance. Additionally, each conductive segment 1144a, 1145a can have a height (e.g., a dimension substantially parallel to the z-axis) of between about 500 Å and about 3500 Å. The height of each conductive segment 1144a, 1145a can vary depending on the conductivity of the material(s) of the segments. For example, in one implementation, the conductive segments 1144a, 1145a include aluminum and have a height of about 1000 Å, while in another implementation, the conductive segments 1144a and/or connecting segments 1145a can include molybdenum and have a height of about 2200 Å. Thus, the conductive segments 1144a can at least partially define a volume 1142a within each sensing element 1140a. The volume 1142a can include the space defined, at least partially, by the area between the conductive segments 1144a and extending the distance of the height of the conductive segments. The sensing element 1140a can include a transparent and non-conductive material, for example, glass, air, and/or a transparent dielectric material, that make up the volume 1142a such that light may pass through the volumes 1142a without being appreciably absorbed and/or reflected and such that the volumes 1142a do not electrically connect the conductive segments 1144a and connecting segments 1145a to one another.

Similarly, each of the set of conductive columns 1104a includes a plurality of conductive segments 1154a that are connected to one another to form a singular conductive column 1104a. Some of the conductive segments 1154a can define a sensing element 1150a and the sensing elements 1150a can be electrically connected to each other by connecting segments 1155a. The sensing elements 1150a can include various shapes including, for example, squares, diamonds, polygons, and curvilinear shapes. Each conductive segment 1154a and connecting 1155a can have a width (e.g., a dimension substantially parallel to the y-axis) of between about 3 μm and about 20 μm such that the width is difficult to observe by a human observer. Additionally, each conductive segment 1154a and connecting segments 1155a can have a height (e.g., a dimension substantially parallel to the z-axis) of between about 500 Å and about 3500 Å. The height of each conductive segment 1154a and connecting segment 1155a can vary depending on the conductivity of the material(s) of the segments. For example, in one implementation, the conductive segments 1154a and connecting segments 1155a include aluminum and have a height of about 1000 Å, while in another implementation, the conductive segments 1154a and connecting segments 1155a include molybdenum and have a height of about 2200 Å. Thus, the conductive segments 1154a can at least partially define a volume 1152a within each sensing element 1150a. The sensing element 1150a can include a transparent and non-conductive material, for example, glass, air, and/or a dielectric material, that make up the volume 1152a such that light may pass through the volumes 1152a without being appreciably absorbed and/or reflected and such that the volumes 1152a do not electrically connect the conductive segments 1144a and connecting segments 1145a to one another and/or electrically connect the set of conductive columns 1104a to the set of conductive rows 1106a. Thus, the conductive rows and columns 1106a, 1104a can be used to form a sensor array 1100a that includes non-transparent conductive elements (e.g., the conductive rows and columns 1106a, 1104a) configured to receive a signal from a sensor circuit and transparent non-conductive elements (e.g., the volumes 1142a, 1152a) configured to allow light to pass through with minimal absorption and/or reflection (e.g., with minimal lost light). The pitch or distance between adjacent conductive rows 1106a may range from less than 0.05 mm to greater than 5.0 mm. Similarly, the pitch or distance between adjacent conductive columns 1104a may range from less than 0.05 mm to greater than 5.0 mm.

In the implementation schematically illustrated in FIG. 11A, a signal can be applied to each conductive row 1106a and each conductive column 1104a and mutual capacitances between adjacent conductive rows and columns 1106a, 1104a can be measured along with self capacitances to determine presence of a conductive object near to a location of the sensing array 1100a. When mutual capacitances are measured to sense a conductive object, the sensing elements 1140a, 1150a can include complimentary segments 1144a′, 1154a′ that extend substantially parallel to one another. Complimentary conductive segments 1144a′, 1154a′ can result from the complimentary shapes of sensing elements 1140a, 1150a and/or can result with differently shaped sensing elements 1140a, 1150a as discussed in more detail below.

Turning now to FIG. 11B, a second implementation of a sensing array 1100b is schematically illustrated. The sensing array 1100b includes a set of conductive rows 1106b formed of conductive segments 1144b and connecting segments 1145b and a set of conductive columns 1104b formed of conductive segments 1154b and connecting segments 1155b. Each of the set of conductive rows 1106b includes a plurality of sensing elements 1140b formed of conductive segments 1144b. Similarly, each of the set of conductive columns 1104b includes a plurality of sensing elements 1150b formed of conductive segments 1154b. Sensing elements 1150b are complimentary to sensing elements 1140b such that a conductive segment 1144b′ of sensing element 1140b extends diagonally and generally parallel to a conductive segment 1154b′ of another sensing element 1150b.

In contrast to the sensing elements 1140a, 1150a discussed with reference to FIG. 11A, sensing elements 1140b, 1150b include two volumes 1142b, 1152b disposed on opposite sides of a center conductive segment 1144b, 1154b. As the sensing elements 1140b, 1150b include additional conductive segments, the total collective cross-sectional area of the conductive segments 1144b, 1154b in each sensing element 1140b, 1150b can increase, which lowers the electrical resistance of each sensing element 1140b, 1150b compared to the electrical resistances of sensing elements 1140a, 1150a illustrated in FIG. 11A. Decreasing the resistance of the sensing elements 1140b, 1150b, and thus, of the sensing array 1100b, can reduce an RC time delay for a connected sensing circuit (not shown) and increase the sampling rate of the capacitance touch sensing.

FIG. 11C schematically illustrates another implementation of a sensing array 1100c including a set of conductive rows 1106c and a set of conductive columns 1104c. Each of the set of conductive rows 1106c includes a plurality of sensing elements 1140c formed of conductive segments 1144c. Similarly, each of the set of conductive columns 1104c includes a plurality of sensing elements 1150c formed of conductive segments 1154c. Sensing elements 1150c are complimentary to sensing elements 1140c such that a conductive segment 1144c′ of sensing element 1140c extends diagonally and generally parallel to a conductive segment 1154c′ of another sensing element 1150c.

Each sensing element 1140c, 1150c includes three volumes 1142c, 1152c defined at least partially by conductive segment segments 1144c, 1154c, respectively. The sensing elements 1140c, 1150c can include a transparent and non-conductive material, for example, glass, air, and/or a dielectric material, that make up the volumes 1142c, 1152c such that light may pass through the volumes 1142c, 1152c without being appreciably absorbed and/or reflected. Thus, the sensing array 1100c can be disposed at least partially over a reflective display such that ambient light incident on the sensing array 1100c is not lost when passing through the volumes 1142c, 1152c. As discussed above with reference to FIG. 11B, the resistance of each sensing element 1140c, 1150c can decrease with each additional conductive segment 1144c, 1154c as the total collective cross-sectional area of the conductive segments 1144c, 1154c increases. A person having ordinary skill in the art will readily understand that the resistances of the various sensing elements disclosed herein can be adjusted by including additional conductive segments in the sensor elements. The additional conductive segments also can increase the sensitivity of self-capacitance sensing as a conductive object positioned over the center of a given sensor element will be more proximal to a conductive segment.

FIG. 11D schematically illustrates another implementation of a sensing array 1100d including a set of conductive rows 1106d and a set of conductive columns 1104d extending generally perpendicular to each of the set of conductive rows 1106d. The conductive rows and columns 1106d, 1104d each include sensing elements 1140d, 1150d that overlap one another. In the illustrated implementation, the sensing elements 1140d, 1150d include round or curvilinear shapes formed of the conductive segments 1144d, 1154d. The sensing elements 1140d, 1150d can be linked together by connecting segments 1145d, 1155d that are electrically conductive such that a sensing circuit (not shown) can be electrically coupled to each of the conductive rows and columns 1106d, 1104d, respectively. Each sensing element 1140d, 1150d at least partially defines a volume 1142d, 1152d within the conductive segments 1144d, 1154d of the sensing element 1140d, 1150d. In some implementations, the sensing elements 1140d of the set of conductive rows 1106d can define a volume 1142d that is greater than a volume 1152d defined by the sensing elements 1150d of the set of conductive columns 1104d. The sensing elements 1140d, 1150d can include optically transparent and non-conductive material(s) that make up volumes 1142d, 1152d in order to allow light to pass through the volumes 1142d, 1152d without significant absorption and/or reflection of the light.

FIG. 11E schematically illustrates another implementation of a sensing array 1100e including a set of conductive rows 1106e and a set of conductive columns 1104e extending generally perpendicular to each of the set of conductive rows 1106e. The set of conductive rows 1106e and the set of conductive columns 1104e are each disposed within a sensing region 1108e that may be incorporated in a capacitive touch sensing device. As illustrated, each of the set of conductive columns 1104e extends generally parallel to the y-axis (e.g., vertical) and each of the set of conductive rows 1106e extends generally parallel to the x-axis (e.g., horizontal). Both the set of conductive rows 1106e and the set of conductive columns 1104e have a height dimension measured along the z-axis.

Each of the set of conductive columns 1104e extends generally straight in a vertical direction and each of the set of conductive rows 1106e includes a plurality of conductive segments 1147e that extend horizontally and a plurality of conductive segments 1148e that extend vertically to form a conductive row 1106e that generally extends horizontally from right to left. Each of the set of conductive columns 1104e can be disposed between at least two vertically extending conductive segments 1148e on each of the set of conductive rows 1106e. The vertical extending conductive segments 1148e and the vertically extending conductive columns 1104e can define volumes 1162e therebetween. Optically transparent and non-conductive material(s), for example, a transparent dielectric, can make up the volumes 1162e to allow light to pass through the volumes 1162e without significant absorption and/or reflection of the light.

Turning now to FIG. 11F, another implementation of a sensing array 1100f is schematically illustrated. The sensing array includes a set of conductive rows 1106f and a set of conductive columns 1104f extending generally perpendicular to each of the set of conductive rows 1106f. The set of conductive rows 1106f and the set of conductive columns 1104f are each disposed within a sensing region 1108f that may be incorporated in a capacitive touch sensing device. As illustrated, each of the set of conductive columns 1104f extends generally parallel to the y-axis (e.g., vertical) and each of the set of conductive rows 1106f extends generally parallel to the x-axis (e.g., horizontal). Both the set of conductive rows 1106f and the set of conductive columns 1104f have a height dimension measured along the z-axis.

Each of the set of conductive columns 1104f includes a vertical a segment 1159f that extends generally straight in a vertical direction (e.g., generally parallel to the y-axis). The set of conductive columns 1104f also each include a plurality of segments 1158f that extend horizontally from each conductive column 1104f and a plurality of segments 1157f that extend vertically from each of the horizontal segments 1158f. Thus, segments 1159f, 1158f and 1157f form a plurality of u-shapes along the length of each of the set of conductive columns 1104f. Each of the set of conductive rows 1106f includes a plurality of conductive segments 1147f that extend horizontally and a plurality of conductive segments 1148f that extend vertically to form a conductive row 1106f that generally extends horizontally from right to left. Each segment 1159f of the set of conductive columns 1104f can be disposed between at least two vertically extending conductive segments 1148f. The set of conductive rows 1106f and the set of conductive columns 1104f at least partially define various volumes 1162f, 1164f therebetween. Optically transparent and non-conductive material(s), for example, a transparent dielectric, can make up the volumes 1162f, 1164f to allow light to pass through the volumes 1162f, 1164f without significant absorption and/or reflection of the light.

FIG. 11G schematically illustrates another implementation of a sensor array 1100g including a set of conductive rows 1106g extending generally parallel to a first direction (e.g., generally horizontal or parallel to the x-axis) and a set of conductive columns 1104g extending generally perpendicular to the first direction (e.g., generally vertical or parallel to the y-axis). Each of the set of conductive rows 1106g includes a plurality of segments 1149g that extend from the conductive rows 1106g at an angle relative to the x and y axes. Similarly, each of the set of conductive columns 1104g includes a plurality of segments 1159g that extend from the conductive columns 1104g at an angle relative to the x and y axes. In some implementations, the plurality of segments 1149g, 1159g can extend at the same angles relative to the x and y axes such that a segment 1149g extends generally parallel to a segment 1159g. Thus, the segments 1149g, 1159g can partially define a volume 1162g therebetween. The volume 1162g can be at least partially defined by the lengths of the segments 1149g, 1159g (e.g., the lengths of the segments measured in a plane parallel to the x-y plane) and the heights of the segments 1149g, 1159g (e.g., the heights of the segments measured along the z-axis). Optically transparent and non-conductive material(s), for example, a transparent dielectric, can make up the volumes 1162g to allow light to pass through the volumes 1162g without significant absorption and/or reflection of the light.

FIG. 11H schematically illustrates another implementation of a sensor array 1100h including a set of conductive rows 1106h extending generally parallel to a first direction (e.g., generally horizontal or parallel to the x-axis) and a set of conductive columns 1104h extending generally perpendicular to the first direction (e.g., generally vertical or parallel to the y-axis). Each of the set of conductive rows 1106h extends generally in a zigzag path forming an angular shape with sharp turns in alternating directions. Each of the set of conductive rows 1106h includes a first plurality of segments 1141h extending diagonally and generally parallel to a first direction and a second plurality of segments 1143h interconnecting the segments 1141h and extending diagonally and generally parallel to a second direction. In this way, the first plurality of segments 1141h form the zigs of the zigzag shape and the second plurality of segments 1143h form the zags of the zigzag shape.

Similarly, each of the set of conductive columns 1104h extends generally in a zigzag path forming an angular shape with sharp turns in alternating directions. Each of the set of conductive columns 1104h includes a first plurality of segments 1151h extending diagonally and generally parallel to a first direction and a second plurality of segments 1153h interconnecting the segments 1151h and extending diagonally and generally parallel to a second direction. In this way, the first plurality of segments 1151h form the zigs of the zigzag shape and the second plurality of segments 1153h form the zags of the zigzag shape.

As schematically illustrated in FIG. 11H, the set of conductive rows 1106h can overlap the set of conductive columns 1104h to form a sensor region 1108h. The shapes of the set of conductive rows 1106h can be complimentary to the shapes of the set of conductive columns 1104h such that the second plurality of segments 1143h of the set of conductive rows 1106h extend generally parallel to the second plurality of segments 1153h of the set of conductive columns 1104h. In this way, a segment 1143h and a segment 1153h can partially define a volume 1162h therebetween. The volume 1162h can be at least partially defined by the lengths of the segments 1143h, 1153h (e.g., the lengths of the segments measured in a plane parallel to the x-y plane) and the heights of the segments 1143h, 1153h (e.g., the heights of the segments measured along the z-axis). Optically transparent and non-conductive material(s), for example, a transparent dielectric, can make up the volumes 1162h to allow light to pass through the volumes 1162h without significant absorption and/or reflection of the light.

FIG. 111 schematically illustrates another implementation of a sensing array 1100i. The sensing array 1100i includes a set of conductive rows 1106i and a set of conductive columns 1104i extending generally perpendicular to each of the set of conductive rows 1106i. The set of conductive rows 1106i and the set of conductive columns 1104i are each disposed within a sensing region 1108i that may be incorporated in a capacitive touch sensing device. As illustrated, each of the set of conductive columns 1104i extends generally parallel to the y-axis (e.g., vertical) and each of the set of conductive rows 1106i extends generally parallel to the x-axis (e.g., horizontal). Both the set of conductive rows 1106i and the set of conductive columns 1104i have a height dimension measured along the z-axis.

FIG. 11J shows a close up view of a portion of the example sensing array of FIG. 11I. In some implementations, each of the conductive rows 1106i includes a plurality of sensing elements 1140i and each of the conductive columns 1104i includes a plurality of sensing elements 1150i. The sensing elements 1140i, 1150i can form, or at least partially form, various shapes in a plane parallel to the x-y plane including, for example, squares, diamonds, polygons, and curvilinear shapes. In this way, a volume 1142i can be at least partially defined within a sensing element 1140i and a volume 1152i can be at least partially defined within a sensing element 1150i. Each volume 1142i, 1152i can include a transparent and non-conductive material, for example, glass, air, and/or a transparent dielectric material, such that light may pass through the volumes 1142i, 1152i without being appreciably absorbed and/or reflected and such that the volumes 1142i, 1152i do not electrically connect the conductive rows and columns 1106i, 1104i to one another.

In some implementations, the sensing elements 1140i each include at least one conductive segment 1147i that extends from the sensing element 1140i. Likewise, each sensing element 1150i can optionally include at least one conductive element 1157i that extends from the sensing element 1150i. The conductive segments 1147i extending from sensing elements 1140i may overlap a portion of one or more sensing elements 1150i and the conductive segments 1157i extending from sensing elements 1150i may overlap a portion of one or more sensing elements 1140i. The conductive segments 1147i, 1157i can at least partially define various volumes 1162i between one or more sensing elements 1150i, 1140i and the conductive segments 1147i, 1157i. Optically transparent and non-conductive material(s), for example, a transparent dielectric, can make up these volumes 1162i to allow light to pass through the volumes 1162i without significant absorption and/or reflection of the light.

As discussed above, the sensor arrays 1108 described with reference to FIGS. 11A-11J include conductive rows and columns 1106, 1104 that are non-transparent and transparent non-conductive volumes 1142, 1152, 1162, and 1164 such that the conductive rows and columns 1106, 1104 can be electrically coupled to sensing circuitry while ambient light incident on the arrays 1108 can pass through the volumes without significant absorption and/or reflection (e.g., without significant lost light). The conductive rows and columns 1106, 1104 can be configured with dimensions that make them hard to detect by a human observer such that an underlying display is substantially viewable through the sensor array 1108. However, because the non-transparent conductive rows and columns 1106, 1104 include non-transparent conductive materials, ambient light incident on the conductive rows and columns 1106, 1104 may be reflected toward a viewer affecting the contrast of an underlying display. Accordingly, in some implementations, one or more reflectivity control layers can be disposed over one or more portions of conductive rows and/or columns in a sensor array to limit the reflectance from these non-transparent structures.

In some implementations, a reflectivity control layer can include a polymer coated over one or more portions of a conductive row or column to limit the reflectance from the underlying conductive row or column. For example, a dark polymer layer can be disposed over a conductive row or column to limit the reflectance therefrom and improve the overall contrast of an underlying reflective display. In some other implementations, black chrome, e.g., chromium dioxide, can be disposed over a conductive row or column to limit the reflectance therefrom.

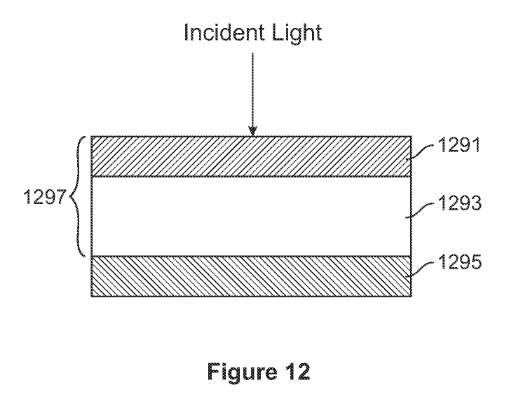

FIG. 12 shows a cross-section of an example implementation of a conductive structure with a reflectivity control layer disposed over the conductive structure. As shown in FIG. 12, in some implementations, the reflectivity control layer can include an interferometric stack 1297 disposed over the conductive structure 1295. In some implementations, the conductive structure 1295 can include a conductive row or column, for example, one of the rows 1106 or columns 1104 discussed above with reference to FIGS. 11A-11J. In the interferometric stack 1297, the function of the interferometric reflector (e.g., reflector 14 of FIG. 8E) can be served by the conductive structure 1295 being masked. Interferometric stack 1297 can include an absorber layer 1291 and an optical resonant cavity layer 1293 disposed between the absorber layer 1291 and the conductive structure 1295. Light incident on the interferometric stack 1297 results in little or no visible reflection from the underlying conductive structure 1295 due to the principles of optical interference discussed above. The interferometric effect can be governed by the thickness and material(s) of the absorber layer 1291 and optical resonant cavity layer 1293. Accordingly, the masking effect is not as susceptible to fading over time compared to common dyes or paints.

The materials and dimensions of the absorber layer 1291 and the optical resonant cavity layer 1293 can be selected to reduce the reflectance of visible light from the underlying reflective conductive structure 1295. In some implementations, a reflectivity control layer can have a reflectivity characteristic of less than 30% such that the underlying conductive structure 1295 also has a reflectivity characteristic of less than 30%. As used herein, reflectivity is defined as a ratio of the intensity of visible light reflected from the reflectivity control layer to the intensity of incident visible light upon the top of the reflectivity control layer in the direction normal to the upper surface of the reflectivity control layer. However, a person having ordinary skill in the art will readily appreciate, in view of the disclosure herein, that reflectivity can be reduced to as little as 1-3%, thus resulting in the conductive structures covered by the reflectivity control layer substantially appearing “black.”

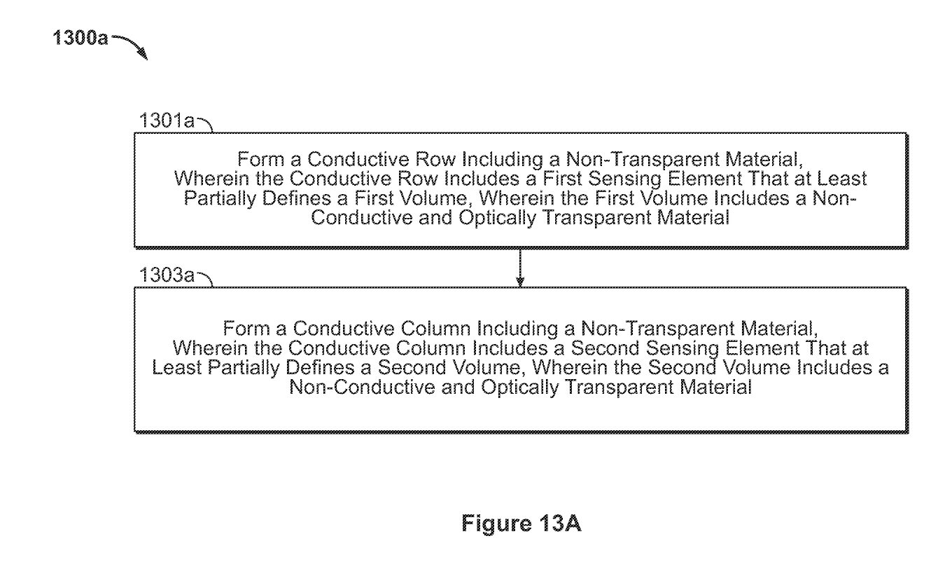

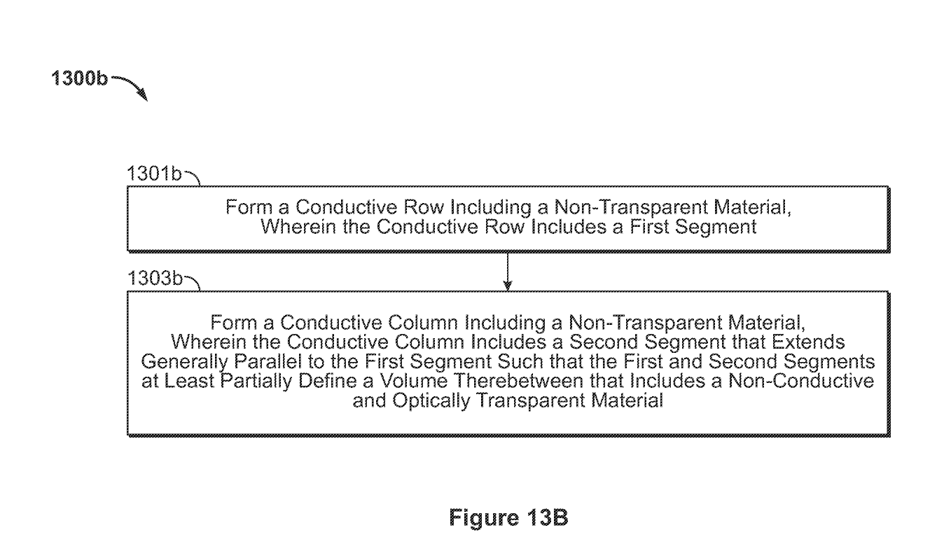

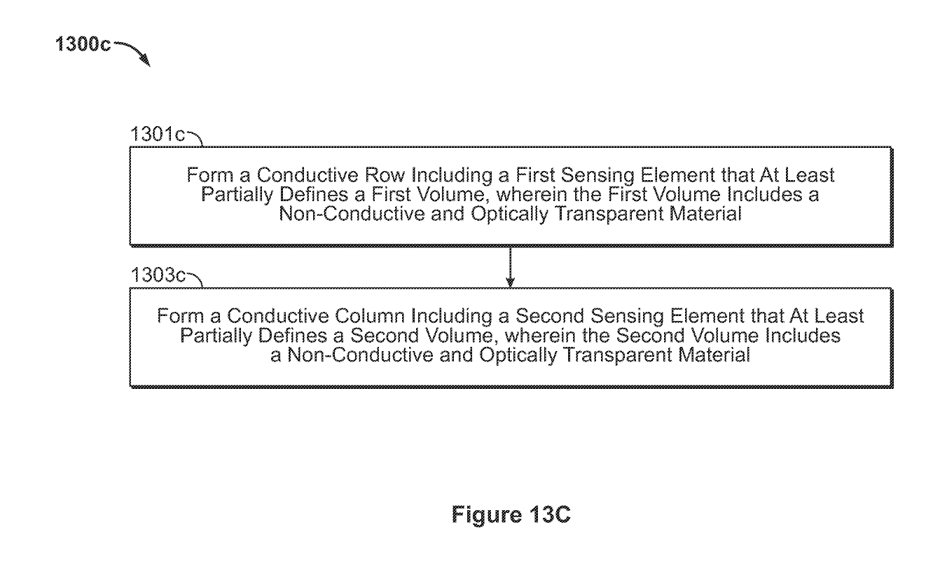

FIGS. 13A-13C show examples of processes for manufacturing a sensor array. FIG. 13A shows a first example process 1300a of manufacturing a sensor array. As shown in block 1301a, example process 1300a includes forming a conductive row including a non-transparent material, wherein the conductive row includes a first sensing element that at least partially defines a first volume, wherein the first volume includes a non-conductive and optically transparent material. As shown in block 1303a, the example process 1300a also includes forming a conductive column including a non-transparent material, wherein the conductive column includes a second sensing element that at least partially defines a second volume, wherein the second volume includes a non-conductive and optically transparent material. In some implementations, the process 1300a can also including disposing the conductive row and the conductive column over a reflective display.

FIG. 13B shows a second example process 1300b of manufacturing a sensor array. As shown in block 1301b, example process 1300b includes forming a conductive row including a non-transparent material, wherein the conductive row includes a first segment. As shown in block 1303b, the method can also include forming a conductive column including a non-transparent material, wherein the conductive column includes a second segment that extends generally parallel to the first segment such that the first and second segments at least partially define a volume therebetween that includes a non-conductive and optically transparent material. In some implementations, the process 1300b can also include disposing the conductive row and the conductive column over a reflective display.

FIG. 13C shows a first example process 1300c of manufacturing a sensor array. As shown in block 1301c, example process 1300c includes forming a conductive row including a first sensing element that at least partially defines a first volume, wherein the first volume includes a non-conductive and optically transparent material. As shown in block 1303c, the example process 1300c also includes forming a conductive column including a second sensing element that at least partially defines a second volume, wherein the second volume includes a non-conductive and optically transparent material. The conductive rows and columns may be formed, for example, from a non-transparent material such as aluminum or molybdenum, or from a semi-transparent material such as ITO or a transparent conductive oxide. In some implementations, the process 1300c can also including disposing the conductive row and the conductive column over a reflective display.

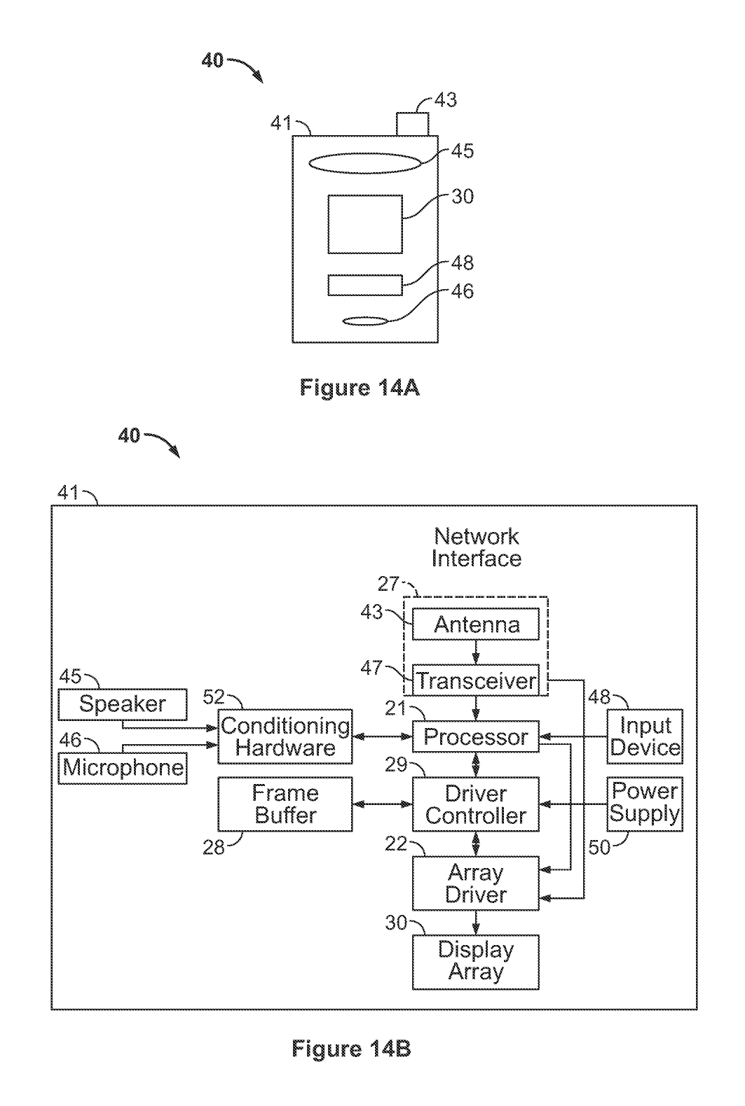

FIGS. 14A and 14B show examples of system block diagrams illustrating a display device 40 that includes a plurality of interferometric modulators. The display device 40 can be, for example, a cellular or mobile telephone. However, the same components of the display device 40 or slight variations thereof are also illustrative of various types of display devices such as televisions, e-readers and portable media players.

The display device 40 includes a housing 41, a display 30, an antenna 43, a speaker 45, an input device 48, and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber, and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an interferometric modulator display, as described herein.

The components of the display device 40 are schematically illustrated in FIG. 14B. The display device 40 includes a housing 41 and can include additional components at least partially enclosed therein. For example, the display device 40 includes a network interface 27 that includes an antenna 43 which is coupled to a transceiver 47. The transceiver 47 is connected to a processor 21, which is connected to conditioning hardware 52. The conditioning hardware 52 may be configured to condition a signal (e.g., filter a signal). The conditioning hardware 52 is connected to a speaker 45 and a microphone 46. The processor 21 is also connected to an input device 48 and a driver controller 29. The driver controller 29 is coupled to a frame buffer 28, and to an array driver 22, which in turn is coupled to a display array 30. A power supply 50 can provide power to all components as required by the particular display device 40 design.

The network interface 27 includes the antenna 43 and the transceiver 47 so that the display device 40 can communicate with one or more devices over a network. The network interface 27 also may have some processing capabilities to relieve, e.g., data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g or n. In some other implementations, the antenna 43 transmits and receives RF signals according to the BLUETOOTH standard. In the case of a cellular telephone, the antenna 43 is designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1×EV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G or 4G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that is readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation, and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of pixels.

In some implementations, the driver controller 29, the array driver 22, and the display array 30 are appropriate for any of the types of displays described herein. For example, the driver controller 29 can be a conventional display controller or a bi-stable display controller (e.g., an IMOD controller). Additionally, the array driver 22 can be a conventional driver or a bi-stable display driver (e.g., an IMOD display driver). Moreover, the display array 30 can be a conventional display array or a bi-stable display array (e.g., a display including an array of IMODs). In some implementations, the driver controller 29 can be integrated with the array driver 22. Such an implementation is common in highly integrated systems such as cellular phones, watches and other small-area displays.

In some implementations, the input device 48 can be configured to allow, e.g., a user to control the operation of the display device 40. The input device 48 can include a keypad, such as a QWERTY keyboard or a telephone keypad, a button, a switch, a rocker, a touch-sensitive screen, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices as are well known in the art. For example, the power supply 50 can be a rechargeable battery, such as a nickel-cadmium battery or a lithium-ion battery. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

Various modifications to the implementations described in this disclosure may be readily apparent to those skilled in the art, and the generic principles defined herein may be applied to other implementations without departing from the spirit or scope of this disclosure. Thus, the disclosure is not intended to be limited to the implementations shown herein, but is to be accorded the widest scope consistent with the claims, the principles and the novel features disclosed herein. The word “exemplary” is used exclusively herein to mean “serving as an example, instance, or illustration.” Any implementation described herein as “exemplary” is not necessarily to be construed as preferred or advantageous over other implementations. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of the IMOD as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A sensor array comprising:
a conductive row including a non-transparent material, wherein the conductive row forms a first sensing element, and wherein the first sensing element at least partially defines a first volume that includes a non-conductive and optically transparent material; and
a conductive column including a non-transparent material, wherein the conductive column forms a second sensing element, and wherein the second sensing element at least partially defines a second volume that includes a non-conductive and optically transparent material.

2. The sensor array of claim 1, further comprising an insulating layer disposed between the conductive row and the conductive column.

3. The sensor array of claim 1, wherein the conductive row includes aluminum or molybdenum.

4. The sensor array of claim 1, wherein the conductive column includes aluminum or molybdenum.

5. The sensor array of claim 1, further comprising a first reflectivity control layer disposed over at least a portion of the conductive row.

6. The sensor array of claim 5, wherein the first reflectivity control layer includes at least one of black chrome, a polymer, and an interferometric stack.

7. The sensor array of claim 6, wherein the interferometric stack includes an absorber layer and an optically transparent layer, wherein the optically transparent layer is disposed at least partially between the absorber layer and the conductive row.

8. The sensor array of claim 5, further comprising a second reflectivity control layer disposed over at least a portion of the conductive column.

9. The sensor array of claim 5, wherein a reflectivity characteristic of the first reflectivity control layer is less than 30%.

10. The sensor array of claim 1, further comprising a reflective display element, wherein the reflective display element is configured to receive light through at least one of the first and second volumes.

11. The sensor array of claim 10, wherein the reflective display element is configured to reflect light through at least one of the first and second volumes.

12. The sensor array of claim 10, wherein the reflective display element includes an interferometric modulator.

13. The sensor array of claim 1, wherein the first sensing element at least partially defines a third volume that includes a non-conductive and optically transparent material and wherein the second sensing element at least partially defines a fourth volume that includes a non-conductive and optically transparent material.

14. The sensor array of claim 13, wherein the first sensing element at least partially defines a fifth volume that includes a non-conductive and optically transparent material and wherein the second sensing element at least partially defines a sixth volume that includes a non-conductive and optically transparent material.

15. The sensor array of claim 1, wherein at least a portion of the conductive row overlaps at least a portion of the conductive column.

16. The sensor array of claim 1, wherein the conductive row comprises a first segment, wherein the conductive column comprises a second segment, and wherein the first segment extends substantially parallel to the second segment.

17. The sensor array of claim 16, wherein a volume defined at least partially between the first segment and the second segment includes at least a portion of the first volume and the second volume.

18. A sensor array comprising:
first means for conducting electric current, wherein the first conductive means includes a non-transparent material, wherein the first conductive means forms a first sensing means, and wherein the first sensing means at least partially defines a volume that includes a non-conductive and optically transparent material; and
second means for conducting electric current, wherein the second conductive means includes a non-transparent material, wherein the second conductive means forms a second sensing means, and wherein the second sensing means at least partially defines a second volume that includes a non-conductive and optically transparent material.

19. The sensor array of claim 18, further comprising a first reflectivity control means disposed over at least a portion of the first conductive means.

20. The sensor array of claim 19, further comprising a second reflectivity control means disposed over at least a portion of the second conductive means.

21. The sensor array of claim 18, wherein at least a portion of the first conductive means overlaps at least a portion of the second conductive means.

22. A method of manufacturing a sensor array, the method comprising:
forming a conductive row including a non-transparent material, wherein the conductive row includes a first sensing element that at least partially defines a first volume, wherein the first volume includes a non-conductive and optically transparent material; and
forming a conductive column including a non-transparent material, wherein the conductive column includes a second sensing element that at least partially defines a second volume, wherein the second volume includes a non-conductive and optically transparent material.

23. The method of claim 22, further comprising disposing the conductive row and the conductive column over a reflective display.

24. The method of claim 22, wherein at least a portion of the conductive row overlaps at least a portion of the conductive column.

25. The method of claim 22, further comprising disposing a reflectivity control layer over at least a portion of the conductive row or conductive column.

26. A sensor array comprising:
a conductive row including a non-transparent material, wherein the conductive row includes a first segment; and
a conductive column including a non-transparent material, wherein the conductive column includes a second segment,
wherein the first segment extends substantially parallel to the second segment, and wherein the first and second segments at least partially define a volume therebetween that includes a non-conductive and optically transparent material.

27. The sensor array of claim 26, wherein the conductive row includes aluminum or molybdenum.

28. The sensor array of claim 26, wherein the conductive column includes aluminum or molybdenum.

29. The sensor array of claim 26, further comprising a first reflectivity control layer disposed over at least a portion of the conductive row.

30. The sensor array of claim 29, further comprising a second reflectivity control layer disposed over at least a portion of the conductive column.

31. The sensor array of claim 26, further comprising a reflective display element, wherein the reflective display element is configured to receive light through the volume.

32. The sensor array of claim 31, wherein the reflective display element is configured to reflect light through the volume.

33. The sensor array of claim 31, wherein the reflective display element includes an interferometric modulator.

34. A sensor array comprising:
first means for conducting electric current, wherein the first conductive means includes a non-transparent material, and wherein the first conductive means includes a first segment; and
second means for conducting electric current, wherein the second conductive means includes a non-transparent material, and wherein the second conductive means includes a second segment,
wherein the first segment extends substantially parallel to the second segment, and wherein the first and second segments at least partially define a volume therebetween that includes a non-conductive and optically transparent material.

35. The sensor array of claim 34, further comprising a first reflectivity control means disposed over at least a portion of the first conductive means.

36. The sensor array of claim 35, further comprising a second reflectivity control means disposed over at least a portion of the second conductive means.

37. A method of manufacturing a sensor array, the method comprising:
forming a conductive row including a non-transparent material, wherein the conductive row includes a first segment;
forming a conductive column including a non-transparent material, wherein the conductive column includes a second segment that extends substantially parallel to the first segment such that the first and second segments at least partially define a volume therebetween that includes a non-conductive and optically transparent material.

38. The method of claim 37, further comprising disposing the conductive row and the conductive column over a reflective display.

39. A sensor array comprising:
a conductive row including a first sensing element, wherein the first sensing element at least partially defines a first volume that includes a non-conductive and optically transparent material; and
a conductive column including a second sensing element, wherein the second sensing element at least partially defines a second volume that includes a non-conductive and optically transparent material.

40. The sensor array of claim 39, further comprising an insulating layer disposed between the conductive row and the conductive column.

41. The sensor array of claim 39, further comprising a first reflectivity control layer disposed over at least a portion of the conductive row.

42. The sensor array of claim 41, wherein the first reflectivity control layer includes at least one of black chrome, a polymer, and an interferometric stack.

43. The sensor array of claim 42, wherein the interferometric stack includes an absorber layer and an optically transparent layer, wherein the optically transparent layer is disposed at least partially between the absorber layer and the conductive row.

44. The sensor array of claim 41, further comprising a second reflectivity control layer disposed over at least a portion of the conductive column.

45. The sensor array of claim 41, wherein a reflectivity characteristic of the first reflectivity control layer is less than 30%.

46. The sensor array of claim 39, further comprising a reflective display element, wherein the reflective display element is configured to receive light through at least one of the first and second volumes.

47. The sensor array of claim 46, wherein the reflective display element is configured to reflect light through at least one of the first and second volumes.

48. The sensor array of claim 46, wherein the reflective display element includes an interferometric modulator.

49. The sensor array of claim 39, wherein the first sensing element at least partially defines a third volume that includes a non-conductive and optically transparent material and wherein the second sensing element at least partially defines a fourth volume that includes a non-conductive and optically transparent material.

50. The sensor array of claim 49, wherein the first sensing element at least partially defines a fifth volume that includes a non-conductive and optically transparent material and wherein the second sensing element at least partially defines a sixth volume that includes a non-conductive and optically transparent material.

51. The sensor array of claim 39, wherein at least a portion of the conductive row overlaps at least a portion of the conductive column.

52. The sensor array of claim 39, wherein the conductive row comprises a first segment, wherein the conductive column comprises a second segment, and wherein the first segment extends substantially parallel to the second segment.

53. The sensor array of claim 52, wherein a volume defined at least partially between the first segment and the second segment includes at least a portion of the first volume and the second volume.

54. The sensor array of claim 39, wherein the conductive row includes a semi-transparent material.

55. The sensor array of claim 54, wherein the semi-transparent material includes a transparent conductive oxide.

56. The sensor array of claim 55, wherein the transparent conductive oxide includes indium tin oxide.

57. A sensor array comprising:
first means for conducting electric current, wherein the first conductive includes a first sensing means, and wherein the first sensing means at least partially defines a volume that includes a non-conductive and optically transparent material; and
second means for conducting electric current, wherein the second conductive includes a second sensing means, and wherein the second sensing means at least partially defines a second volume that includes a non-conductive and optically transparent material.

58. The sensor array of claim 57, further comprising a first reflectivity control means disposed over at least a portion of the first conductive means.

59. The sensor array of claim 58, further comprising a second reflectivity control means disposed over at least a portion of the second conductive means.

60. The sensor array of claim 57, wherein at least a portion of the first conductive means overlaps at least a portion of the second conductive means.

61. A method of manufacturing a sensor array, the method comprising:
forming a conductive row including a first sensing element that at least partially defines a first volume, wherein the first volume includes a non-conductive and optically transparent material; and
forming a conductive column including a second sensing element that at least partially defines a second volume, wherein the second volume includes a non-conductive and optically transparent material.

62. The method of claim 61, further comprising disposing the conductive row and the conductive column over a reflective display.

63. The method of claim 61, wherein at least a portion of the conductive row overlaps at least a portion of the conductive column.

64. The method of claim 61, further comprising disposing a reflectivity control layer over at least a portion of the conductive row or conductive column.
